(19) United States
(12) Patent Application Publication
(10) Pub. No.: US 2024/0186352 A1
(43) Pub. Date: Jun. 6, 2024

(54) IMAGING DEVICE

(71) Applicant: SONY SEMICONDUCTOR SOLUTIONS CORPORATION, Kanagawa (JP)

(72) Inventors: Yoshiaki MASUDA, Kanagawa (JP); Keisuke HATANO, Kanagawa (JP); Hirokazu SEKI, Kumamoto (JP); Atsushi TODA, Kanagawa (JP); Shinichiro NOUDO, Kanagawa (JP); Yusuke OIKE, Kanagawa (JP); Yutaka OOKA, Kanagawa (JP); Naoto SASAKI, Kanagawa (JP); Toshiki SAKAMOTO, Kumamoto (JP); Takafumi MORIKAWA, Kanagawa (JP)

(73) Assignee: SONY SEMICONDUCTOR SOLUTIONS CORPORATION, Kanagawa (JP)

(21) Appl. No.: 18/551,925

(22) PCT Filed: Feb. 9, 2022
(86) PCT No.: PCT/JP2022/005077

§ 371 Date: Sep. 22, 2023

(30) Foreign Application Priority Data
Mar. 30, 2021 (JP) 2021-058787

(51) Int. Cl. H01L 27/146; H04N 25/633; H04N 25/77

(52) U.S. Cl. CPC H01L 27/14627; H01L 27/14621; H01L 27/14623; H01L 27/14632; H01L 27/14636; H04N 25/633; H04N 25/77

(57) ABSTRACT

Provided is an imaging device capable of suppressing an influence of flare. An imaging device according to the present disclosure includes: a pixel region in which a plurality of pixels that performs photoelectric conversion is arranged; an on-chip lens provided on the pixel region; a protective member provided on the on-chip lens; and a resin layer that adheres between the on-chip lens and the protective member, in which when a thickness of the resin layer and the protective member is T, a length of a diagonal line of the pixel region viewed from an incident direction of light is L, and a critical angle of the protective member is θc, T≥L/2/tanθc (Formula 2) or T≥L/4/tanθc (Formula 3) is satisfied.

### TECHNICAL FIELD

The present disclosure relates to an imaging device.

### BACKGROUND ART

A wafer level chip size package (WCSP) in which a semiconductor device is downsized to a chip size has been developed. In a solid-state imaging device of the WCSP, there is a case where a color filter or an on-chip lens is provided on an upper surface side of a semiconductor substrate, and a glass substrate is fixed on the color filter or the on-chip lens via a glass seal resin.

### CITATION LIST

### Patent Document

Patent Document 1: WO 2017/163924 A

### SUMMARY OF THE INVENTION

### Problems to be Solved by the Invention

As described above, in a case where the semiconductor substrate and the glass substrate are fixed by the glass seal resin in a cavity-less structure, when strong light is incident, the light reflected by the on-chip lens on a pixel is further reflected on an upper surface of the glass substrate, and may be incident on another pixel again. As a result, noise called flare may occur due to interference of the re-incident light.

The present technology has been made in view of such a situation, and provides an imaging device capable of suppressing the influence of flare.

### Solutions to Problems

An imaging device according to one aspect of the present disclosure includes: a pixel region in which a plurality of pixels that performs photoelectric conversion is arranged; an on-chip lens provided on the pixel region; a protective member provided on the on-chip lens; and a resin layer that adheres between the on-chip lens and the protective member, in which when a thickness of the resin layer and the protective member is T, a length of a diagonal line of the pixel region viewed from an incident direction of light is L, and a critical angle of the protective member is θc,

T≥L/2/tanθc (Formula 2)

T≥L/4/tanθc (Formula 3)

Formula 2 or 3 is satisfied.

Glass is used for the protective member, and the critical angle θc is about 41.5°.

A concave lens provided on the protective member is further provided.

A convex lens provided on the protective member is further provided.

An actuator that is provided under the protective member or in the protective member and changes a thickness of the protective member is further provided.

A light absorbing film provided on a side surface of the protective member is further provided.

An antireflection film provided on the protective member is further provided.

An infrared cut filter provided on the protective member or in the protective member is further provided.

A Fresnel lens provided on the protective member is further provided.

A metalens provided on the protective member is further provided.

A light shielding film provided on the protective member and including a hole is further provided.

The thickness T is greater than or equal to a first thickness T1 when a width of the pixel is a first width W1 in a plan view viewed from the incident direction, and
when the width of the pixel is a second width W2 (W2<W1) smaller than the first width, the thickness T is greater than or equal to a second thickness T2 (T2>T1) that is thicker than the first thickness T1.

In a case where the second width W2 is ½ of the first width W1, the second thickness T2 is twice the first thickness T1.

A plurality of the on-chip lenses is provided for each of the pixels.

One of the on-chip lenses is provided for the plurality of pixels.

Further provided are: a color filter provided between the pixel region and the on-chip lens; and a first light shielding film provided in the color filter on between the pixels adjacent to each other.

A second light shielding film on the first light shielding film on between the adjacent pixels is further provided.

An imaging device according to one aspect of the present disclosure includes: a pixel region in which a plurality of pixels that performs photoelectric conversion is arranged; an on-chip lens provided on the pixel region; a protective member provided on the on-chip lens; a resin layer that adheres between the on-chip lens and the protective member; and a lens provided on the protective member.

An imaging device according to one aspect of the present disclosure includes: a pixel region in which a plurality of pixels that performs photoelectric conversion is arranged; a plurality of on-chip lenses provided on the pixel region and provided for each of the pixels; a protective member provided on the on-chip lenses; and a resin layer that adheres between the on-chip lenses and the protective member.

An imaging device according to one aspect of the present disclosure includes: a pixel region in which a plurality of pixels that performs photoelectric conversion is arranged; an on-chip lens provided on the pixel region and provided for each of the plurality of pixels; a protective member provided on the on-chip lens; and a resin layer that adheres between the on-chip lens and the protective member.

An imaging device according to one aspect of the present disclosure includes: a pixel region in which a plurality of pixels that performs photoelectric conversion is arranged; an on-chip lens provided on the pixel region and provided for each of the plurality of pixels; a color filter provided between the pixel region and the on-chip lens; a first light shielding film provided in the color filter on between the pixels adjacent to each other; a protective member provided on the color filter and the first light shielding film; and a resin layer that adheres between the on-chip lens and the protective member.

The pixel region includes at least an effective pixel region that outputs a pixel signal used to generate an image.

The pixel region further includes an optical black (OB) pixel region that outputs a pixel signal serving as a reference of dark output.

The OB pixel region is provided so as to surround the periphery of the effective pixel region.

The pixel region further includes a dummy pixel region that stabilizes a characteristic of the effective pixel region.

The dummy pixel region is provided so as to surround a periphery of the OB pixel region.

The pixel region includes an effective photosensitive region in which the pixels including photodiodes are arranged.

The pixel region further includes an external region in which the pixels including the photodiodes are not arranged.

The external region is provided around the effective photosensitive region.

The pixel region further includes a termination region that cuts a semiconductor package from a wafer.

The termination region is provided around the external region.

### BRIEF DESCRIPTION OF DRAWINGS

FIG. 1 is an external schematic view of a solid-state imaging device according to the present disclosure.

FIG. 2 is a view illustrating a substrate configuration of the solid-state imaging device.

FIG. 3 is a diagram illustrating a circuit configuration example of a laminated substrate.

FIG. 4 is a diagram illustrating an equivalent circuit of a pixel.

FIG. 5 is a cross-sectional view illustrating a detailed structure of the solid-state imaging device.

FIG. 6 is a schematic cross-sectional view illustrating a pixel region of the solid-state imaging device.

FIG. 7 is an explanatory diagram illustrating a position where ring flare occurs.

FIG. 8 is a schematic plan view illustrating a pixel sensor substrate and ring flare.

FIG. 9 is a schematic cross-sectional view taken along a diagonal direction of the pixel region in FIG. 8.

FIG. 10 is a schematic cross-sectional view taken along a diagonal direction of the pixel region in FIG. 8.

FIG. 11 is a schematic cross-sectional view illustrating a configuration example of a solid-state imaging device according to a second embodiment.

FIG. 12 is a schematic cross-sectional view illustrating a configuration example of a solid-state imaging device according to a third embodiment.

FIG. 13 is a schematic cross-sectional view illustrating a configuration example of a solid-state imaging device according to a fourth embodiment.

FIG. 14 is a schematic cross-sectional view illustrating a configuration example of a solid-state imaging device according to a fifth embodiment.

FIG. 15 is a schematic cross-sectional view illustrating a configuration example of a solid-state imaging device according to a sixth embodiment.

FIG. 16 is a schematic cross-sectional view illustrating a configuration example of a solid-state imaging device according to a seventh embodiment.

FIG. 17 is a schematic cross-sectional view illustrating a configuration example of a solid-state imaging device according to a modification example of the sixth embodiment.

FIG. 18 is a schematic cross-sectional view illustrating a configuration example of a solid-state imaging device according to an eighth embodiment.

FIG. 19 is a schematic cross-sectional view illustrating a configuration example of a solid-state imaging device according to a ninth embodiment.

FIG. 20 is a schematic cross-sectional view illustrating a configuration example of a solid-state imaging device according to a tenth embodiment.

FIG. 21 is a schematic cross-sectional view illustrating a configuration example of a solid-state imaging device according to an eleventh embodiment.

FIG. 22 is a schematic plan view illustrating a configuration example of the solid-state imaging device according to the eleventh embodiment.

FIG. 23 is a schematic cross-sectional view illustrating a configuration example of a solid-state imaging device according to a twelfth embodiment.

FIG. 24 is a schematic plan view illustrating a configuration example of the solid-state imaging device according to the twelfth embodiment.

FIG. 25 is a schematic cross-sectional view illustrating a configuration example of a solid-state imaging device according to a thirteenth embodiment.

FIG. 26 is a schematic plan view illustrating a configuration example of the solid-state imaging device according to the thirteenth embodiment.

FIG. 27 is a schematic cross-sectional view illustrating a configuration example of a solid-state imaging device according to a fourteenth embodiment.

FIG. 28 is a schematic cross-sectional view illustrating a configuration example of a solid-state imaging device according to a fifteenth embodiment.

FIG. 29 is a schematic cross-sectional view illustrating a configuration example of a solid-state imaging device according to a modification example.

FIG. 30 is a diagram illustrating a main configuration example of an imaging device to which the present technology is applied.

FIG. 31 is a cross-sectional view for explaining a configuration of each region of an imaging element.

FIG. 32 is a diagram of a configuration of a semiconductor package in a schematic plan view.

FIG. 33 is a schematic cross-sectional view illustrating a configuration of the semiconductor package.

FIG. 34 is a block diagram illustrating an example of a schematic configuration of a vehicle control system.

FIG. 35 is an explanatory diagram illustrating an example of installation positions of an outside-vehicle information detecting unit and imaging sections.

### MODE FOR CARRYING OUT THE INVENTION

Hereinafter, specific embodiments to which the present technology is applied will be described in detail with reference to the drawings. The drawings are schematic or conceptual, and the ratio of each portion and the like are not necessarily the same as actual ones. In the specification and the drawings, similar elements as those described above with respect to the previously described drawings are denoted by the same reference numerals, and the detailed description thereof is appropriately omitted.

### First Embodiment

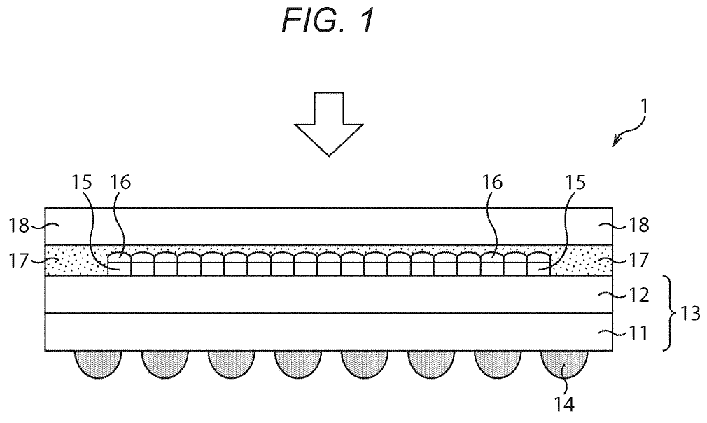

FIG. 1 is a schematic external view of a solid-state imaging device according to a first embodiment.

A solid-state imaging device 1 illustrated in FIG. 1 is a semiconductor package in which a laminated substrate 13 configured by laminating a lower substrate 11 and an upper substrate 12 is packaged. The solid-state imaging device 1 converts light incident from a direction indicated by an arrow in the drawing into an electric signal and outputs the electric signal.

On the lower substrate 11, a plurality of solder balls 14, which is back electrodes for electrical connection with an external substrate (not illustrated), is formed.

On an upper surface of the upper substrate 12, red (R), green (G), or blue (B) color filters 15 and an on-chip lens 16 are formed. Furthermore, the upper substrate 12 is connected to a protective member 18 for protecting the on-chip lens 16 via a seal member 17 in a cavity-less structure. For the protective member 18, for example, a transparent material such as glass, silicon nitride, sapphire, or resin is used. For the seal member 17, for example, a transparent adhesive material such as an acrylic resin, a styrene resin, or an epoxy resin is used.

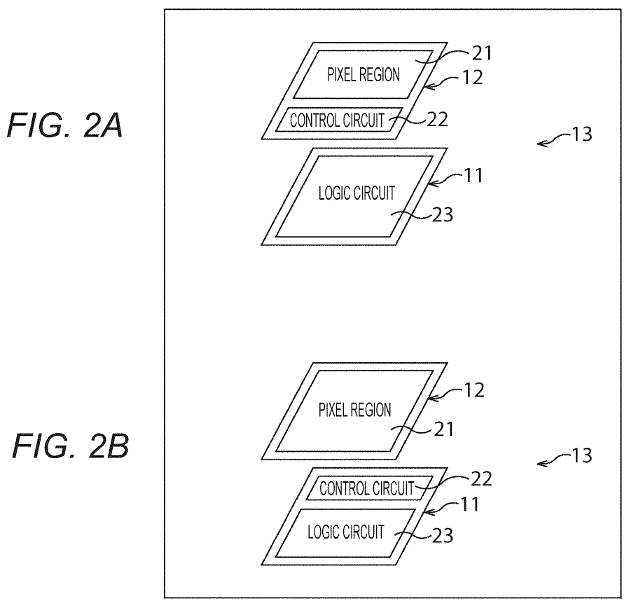

For example, as illustrated in FIG. 2A, a pixel region 21 in which pixels that perform photoelectric conversion are two-dimensionally arranged and a control circuit 22 that controls the pixels are formed on the upper substrate 12, and a logic circuit 23 such as a signal processing circuit that processes pixel signals output from the pixels is formed on the lower substrate 11.

Alternatively, furthermore, as illustrated in FIG. 2B, only the pixel region 21 may be formed on the upper substrate 12, and the control circuit 22 and the logic circuit 23 may be formed on the lower substrate 11.

As described above, the logic circuit 23 or both the control circuit 22 and the logic circuit 23 are formed and laminated on the lower substrate 11 different from the upper substrate 12 of the pixel region 21. As a result, a size of the solid-state imaging device 1 can be reduced as compared with a case where the pixel region 21, the control circuit 22, and the logic circuit 23 are arranged in a planar direction on one semiconductor substrate.

In the following description, the upper substrate 12 on which at least the pixel region 21 is formed will be referred to as a pixel sensor substrate 12, and the lower substrate 11 on which at least the logic circuit 23 is formed will be referred to as a logic substrate 11.

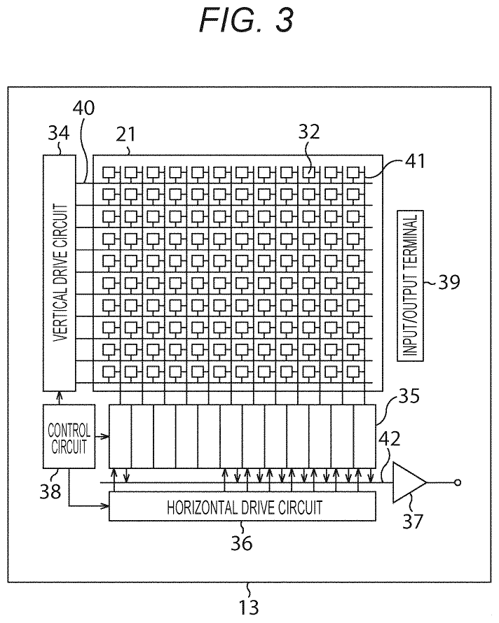

FIG. 3 illustrates a circuit configuration example of the laminated substrate 13.

The laminated substrate 13 includes the pixel region 21 in which pixels 32 are arranged in a two-dimensional array, a vertical drive circuit 34, a column signal processing circuit 35, a horizontal drive circuit 36, an output circuit 37, a control circuit 38, an input/output terminal 39, and the like.

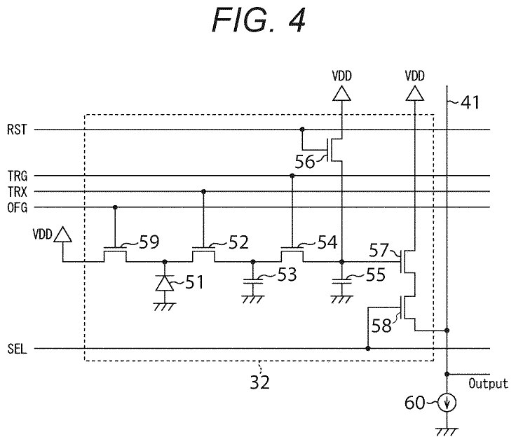

Each of the pixels 32 includes a photodiode as a photoelectric conversion element and a plurality of pixel transistors. An example of a circuit configuration of the pixel 32 will be described later with reference to FIG. 4.

The control circuit 38 receives an input clock and data giving a command of an operation mode and the like, and outputs data of internal information and the like of the laminated substrate 13. That is, the control circuit 38 generates a clock signal and a control signal which serve as a reference for operation of the vertical drive circuit 34, the column signal processing circuit 35, the horizontal drive circuit 36 and the like on the basis of a vertical synchronization signal, a horizontal synchronization signal, and a master clock. The control circuit 38 outputs the generated clock signal and control signal to the vertical drive circuit 34, the column signal processing circuit 35, the horizontal drive circuit 36, and the like.

The vertical drive circuit 34 includes, for example, a shift register, selects a predetermined pixel drive line 40, supplies a pulse for driving the pixels 32 to the selected pixel drive line 40, and drives the pixels 32 in units of rows. That is, the vertical drive circuit 34 sequentially selects and scans each pixel 32 in the pixel region 21 in the vertical direction in units of rows, and supplies a pixel signal based on a signal charge generated according to the amount of received light in the photoelectric conversion unit of each pixel 32 to the column signal processing circuit 35 through a vertical signal line 41.

The column signal processing circuit 35 arranged for each column of the pixels 32 performs signal processing such as noise removal on the signals output from the pixels 32 of one row for each pixel column. For example, the column signal processing circuit 35 performs signal processing such as correlated double sampling (CDS) for removing pixel-specific fixed pattern noise and analogue-to-digital (AD) conversion.

The horizontal drive circuit 36 including a shift register, for example, sequentially selects the column signal processing circuits 35 by sequentially outputting horizontal scanning pulses and outputs the pixel signal from each of the column signal processing circuits 35 to a horizontal signal line 42.

The output circuit 37 performs the signal processing on the signals sequentially supplied from each of the column signal processing circuits 35 through the horizontal signal line 42 to output. There is a case in which the output circuit 37 merely buffers, for example, or a case in which this performs black level adjustment, column variation correction, various types of digital signal processing and the like. An input/output terminal 39 exchanges signals with the outside.

The laminated substrate 13 configured as described above is a complementary metal oxide semiconductor (CMOS) image sensor called a column AD system in which the column signal processing circuits 35 that perform CDS processing and AD conversion processing are arranged for each pixel column.

FIG. 4 illustrates an equivalent circuit of the pixel 32.

The pixel 32 illustrated in FIG. 4 illustrates a configuration that implements an electronic global shutter function.

The pixel 32 includes a photodiode 51 as a photoelectric conversion element, a first transfer transistor 52, a memory unit (MEM) 53, a second transfer transistor 54, a floating diffusion region (FD) 55, a reset transistor 56, an amplification transistor 57, a selection transistor 58, and a discharge transistor 59.

The photodiode 51 is a photoelectric conversion unit that generates and accumulates a charge (signal charge) corresponding to a received light amount. An anode terminal of the photodiode 51 is grounded, and a cathode terminal of the photodiode 51 is connected to the memory unit 53 via the first transfer transistor 52. Furthermore, a cathode terminal of the photodiode 51 is also connected to the discharge transistor 59 for discharging unnecessary charges.

When turned on by a transfer signal TRX, the first transfer transistor 52 reads an electric charge generated by the photodiode 51 and transfers the electric charge to the memory unit 53. The memory unit 53 is a charge holding unit that temporarily holds a charge until the charge is transferred to the FD 55.

When turned on by a transfer signal TRG, the second transfer transistor 54 reads the charge held in the memory unit 53 and transfers the charge to the FD 55.

The FD 55 is a charge holding unit that holds the electric charge read from the memory unit 53 in order to read the electric charge as a signal. When turned on by a reset signal RST, the reset transistor 56 resets the potential of the FD 55 by discharging the charge accumulated in the FD 55 to the constant voltage source VDD.

The amplification transistor 57 outputs a pixel signal corresponding to an electric potential of the FD 55. That is, the amplification transistor 57 constitutes a source follower circuit with a load MOS 60 as a constant current source, and a pixel signal indicating a level according to the charge accumulated in the FD 55 is output from the amplification transistor 57 to the column signal processing circuit 35 (FIG. 3) via the selection transistor 58. The load MOS 60 is disposed, for example, in the column signal processing circuit 35.

The selection transistor 58 is turned on when the pixel 32 is selected by a selection signal SEL, and outputs a pixel signal of the pixel 32 to the column signal processing circuit 35 via the vertical signal line 41.

When turned on by a discharge signal OFG, the discharge transistor 59 discharges unnecessary electric charge accumulated in the photodiode 51 to the constant voltage source VDD.

The transfer signals TRX and TRG, the reset signal RST, the discharge signal OFG, and the selection signal SEL are supplied from the vertical drive circuit 34 via the pixel drive line 40.

An operation of the pixel 32 will be briefly described.

First, before exposure is started, the discharge transistor 59 is turned on by supplying the discharge signal OFG at the high level to the discharge transistor 59, the charge accumulated in the photodiode 51 is discharged to the constant voltage source VDD, and the photodiodes 51 of all the pixels are reset.

After the photodiode 51 is reset, when the discharge transistor 59 is turned off by a discharge signal OFG at a Low level, exposure is started in all the pixels in the pixel region 21.

When a predetermined exposure time has elapsed, the first transfer transistor 52 is turned on by the transfer signal TRX in all the pixels of the pixel region 21, and the charge accumulated in the photodiode 51 is transferred to the memory unit 53.

After the first transfer transistor 52 is turned off, the charges held in the memory unit 53 of each pixel 32 are sequentially read out to the column signal processing circuit 35 in units of rows. In the read operation, the second transfer transistor 54 of the pixel 32 of the read row is turned on by the transfer signal TRG, and the charge held in the memory unit 53 is transferred to the FD 55. Then, when the selection transistor 58 is turned on by the selection signal SEL, a signal indicating a level corresponding to the charge accumulated in the FD 55 is output from the amplification transistor 57 to the column signal processing circuit 35 via the selection transistor 58.

As described above, in the pixel 32 having the pixel circuit in FIG. 4, the exposure time is set to be the same in all the pixels of the pixel region 21, and after the exposure is finished, the charge is temporarily held in the memory unit 53, and the global shutter system operation (imaging) of sequentially reading the charge from the memory unit 53 in units of rows is possible.

Note that the circuit configuration of the pixel 32 is not limited to the configuration illustrated in FIG. 4, and for example, a circuit configuration that does not include the memory unit 53 and performs an operation by a so-called rolling shutter system can be adopted.

Furthermore, the pixel 32 may have a shared pixel structure in which some pixel transistors are shared by a plurality of the pixels. For example, a configuration in which the first transfer transistor 52, the memory unit 53, and the second transfer transistor 54 are included in units of pixels 32, and the FD 55, the reset transistor 56, the amplification transistor 57, and the selection transistor 58 are shared by the plurality of pixels such as four pixels can be adopted.

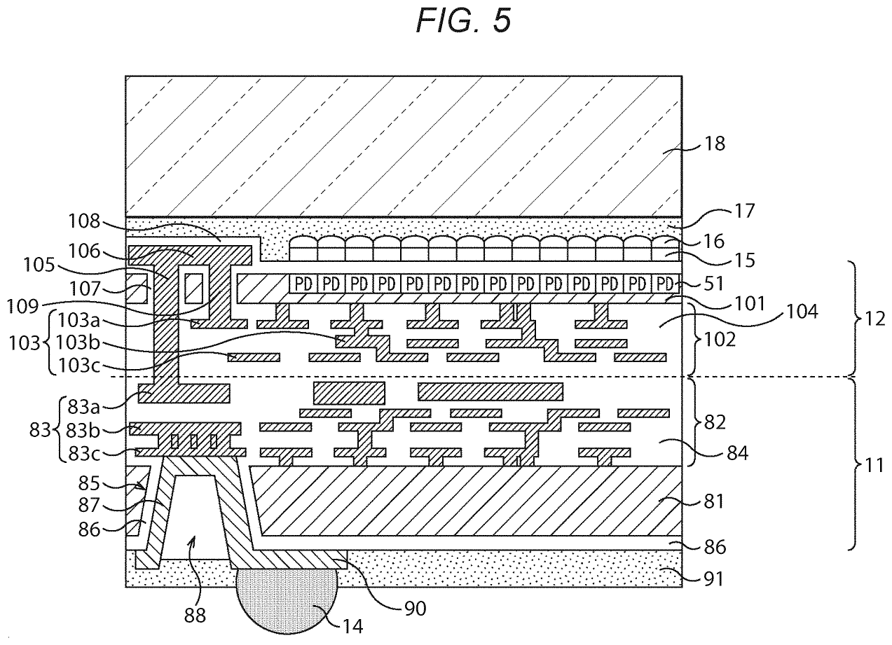

Next, the laminated substrate 13 will be described with reference to FIG. 5. FIG. 5 is an enlarged cross-sectional view illustrating a part of the solid-state imaging device 1.

In the logic substrate 11, a multilayer wiring layer 82 is formed on an upper side (a side of the pixel sensor substrate 12) of a semiconductor substrate 81 (hereinafter, referred to as a silicon substrate 81) constituted by, for example, silicon (Si). The multilayer wiring layer 82 constitutes the control circuit 22 and the logic circuit 23 in FIG. 2.

The multilayer wiring layer 82 includes a plurality of wiring layers 83 including an uppermost wiring layer 83a closest to the pixel sensor substrate 12, an intermediate wiring layer 83b, a lowermost wiring layer 83c closest to the silicon substrate 81, and the like, and an inter-layer insulating film 84 formed between the wiring layers 83.

The plurality of wiring layers 83 is formed using, for example, copper (Cu), aluminum (Al), tungsten (W), or the like, and the inter-layer insulating film 84 is formed using, for example, a silicon oxide film, a silicon nitride film, or the like. In each of the plurality of wiring layers 83 and the inter-layer insulating film 84, all the layers may include the same material, or two or more materials may be used depending on the layer.

A silicon through hole 85 penetrating the silicon substrate 81 is formed at a predetermined position of the silicon substrate 81, and a connection conductor 87 is embedded in an inner wall of the silicon through hole 85 via an insulating film 86 to form a through silicon via (TSV) 88. The insulating film 86 may be formed using, for example, a SiO2 film, a SiN film, and the like.

Note that, in the through silicon via 88 illustrated in FIG. 5, the insulating film 86 and the connection conductor 87 are formed along the inner wall surface, and the inside of the silicon through hole 85 is hollow. However, depending on the inner diameter, the entire inside of the silicon through hole 85 may be filled with the connection conductor 87. In other words, the inside of the through hole may be filled with a conductor, or a part of the through hole may be a cavity. It similarly applies to a through chip via (TCV) 105 and the like as described later.

The connection conductor 87 of the through silicon via 88 is connected to the rewiring 90 formed on the lower surface side of the silicon substrate 81, and the rewiring 90 is connected to the solder ball 14. The connection conductor 87 and the rewiring 90 can be formed by, for example, copper (Cu), tungsten (W), titanium (Ti), tantalum (Ta), titanium tungsten alloy (TiW), polysilicon, or the like.

Furthermore, on the lower surface side of the silicon substrate 81, a solder mask (solder resist) 91 is formed so as to cover the rewiring 90 and the insulating film 86 except for the region where the solder balls 14 are formed.

On the other hand, in the pixel sensor substrate 12, a multilayer wiring layer 102 is formed on a lower side (side of the logic substrate 11) of a semiconductor substrate 101 (hereinafter, referred to as a silicon substrate 101) constituted by, for example, silicon (Si). The multilayer wiring layer 102 constitutes the pixel circuit of the pixel region 21 in FIG. 2.

The multilayer wiring layer 102 includes a plurality of wiring layers 103 including an uppermost wiring layer 103a closest to the silicon substrate 101, an intermediate wiring layer 103b, a lowermost wiring layer 103c closest to the logic substrate 11, and the like, and an inter-layer insulating film 104 formed between the wiring layers 103.

As the material used as the plurality of wiring layers 103 and the inter-layer insulating film 104, the same type of material as the material of the wiring layer 83 and the inter-layer insulating film 84 described above can be adopted. Furthermore, the plurality of wiring layers 103 and the inter-layer insulating film 104 may be formed by using one or two or more materials, which is similar to the wiring layer 83 and the inter-layer insulating film 84 described above.

Note that, in the example of FIG. 5, the multilayer wiring layer 102 of the pixel sensor substrate 12 includes the three wiring layers 103, and the multilayer wiring layer 82 of the logic substrate 11 includes the four wiring layers 83. However, the total number of wiring layers is not limited thereto, and any number of wiring layers can be formed.

In the silicon substrate 101, a photodiode 51 formed by a PN junction is formed for each pixel 32.

Furthermore, although not illustrated, a plurality of pixel transistors such as a first transfer transistor 52 and a second transfer transistor 54, a memory unit (MEM) 53, and the like is also formed in the multilayer wiring layer 102 and the silicon substrate 101.

At a predetermined position of the silicon substrate 101 where the color filter 15 and the on-chip lens 16 are not formed, a through silicon via 109 connected to the wiring layer 103a of the pixel sensor substrate 12 and a through chip via 105 connected to the wiring layer 83a of the logic substrate 11 are formed.

The through chip via 105 and the through silicon via 109 are connected by a connection wiring 106 formed on the upper surface of the silicon substrate 101. Furthermore, an insulating film 107 is formed between each of the through silicon via 109 and the through chip via 105 and the silicon substrate 101. Moreover, on the upper surface of the silicon substrate 101, a color filter 15 and an on-chip lens 16 are formed via an insulating film (planarization film) 108.

As described above, the laminated substrate 13 of the solid-state imaging device 1 illustrated in FIG. 1 has a laminated structure in which a side of the multilayer wiring layer 82 of the logic substrate 11 and a side of the multilayer wiring layer 102 of the pixel sensor substrate 12 are bonded together. In FIG. 5, a bonding surface between the multilayer wiring layer 82 of the logic substrate 11 and the multilayer wiring layer 102 of the pixel sensor substrate 12 is indicated by a broken line.

Furthermore, in the laminated substrate 13 of the solid-state imaging device 1, the wiring layer 103 of the pixel sensor substrate 12 and the wiring layer 83 of the logic substrate 11 are connected by two through electrodes of the through silicon via 109 and the through chip via 105, and the wiring layer 83 of the logic substrate 11 and the solder ball (back electrode) 14 are connected by the through silicon via 88 and the rewiring 90. As a result, the plane area of the solid-state imaging device 1 can be minimized.

Moreover, by forming the space between the laminated substrate 13 and the protective member 18 into a cavity-less structure and bonding them by the seal member 17, the structure can also be lowered in a height direction.

Therefore, according to the solid-state imaging device 1 illustrated in FIG. 1, a semiconductor device (semiconductor package) that is further downsized can be achieved.

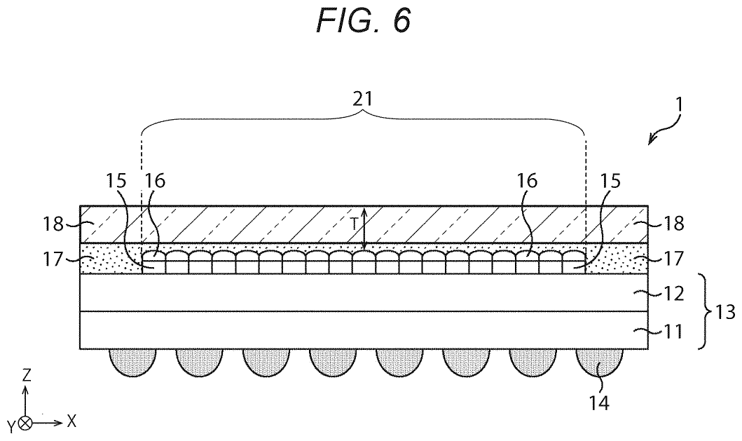

FIG. 6 is a schematic cross-sectional view illustrating the pixel region 21 of the solid-state imaging device. The pixel region 21 is a region including the pixels (effective pixels) 32, and the color filter 15 and the on-chip lens 16 are provided on the pixel region 21. Note that the pixel region 21 may include optical black (OB) pixels and/or dummy pixels as described later. The seal member 17 as a resin layer is provided on the on-chip lens 16, and the protective member 18 is provided thereon. The protective member 18 is bonded onto the on-chip lens 16 by the seal member 17. Thicknesses of the seal member 17 and the protective member 18 on the on-chip lens 16 are denoted by T.

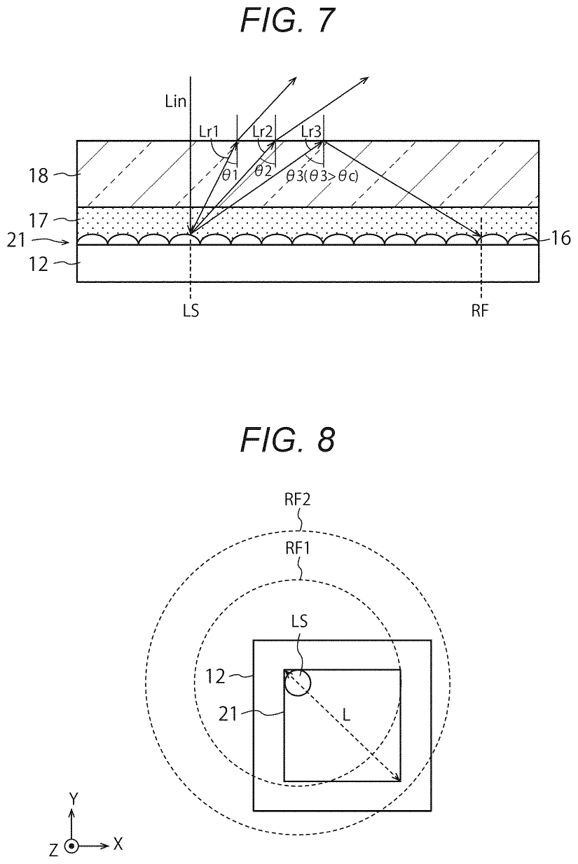

FIG. 7 is an explanatory diagram illustrating a position where ring flare occurs. Note that, in FIG. 7, illustration of a configuration under the on-chip lens 16 is omitted.

Incident light Lin enters the on-chip lens 16 via the protective member 18 and the seal member 17. Most of the incident light Lin incident on the on-chip lens 16 is detected in the pixel region 21. On the other hand, a part of the incident light Lin is reflected by a surface of the on-chip lens 16. A light source LS of reflected light indicates a light source of the reflected light obtained by reflecting the incident light Lin by the on-chip lens 16. The reflected light Lr1 to Lrm (m is an integer) is diffracted reflected light, for example, Lr1 is first-order diffracted light, Lr2 is second-order diffracted light, Lr3 is third-order diffracted light, and the reflected light Lrm is m-order diffracted light. m is a diffraction order. Note that, in FIG. 7, high order diffracted light having the diffraction order m of 4 or more is not illustrated.

Here, when a diffraction angle of the reflected light Lrm is θm, a relationship between the diffraction order m and the diffraction angle θm is expressed by the following Formula 1.

n×d×sin θm=m×λ (Formula 1)

Note that n is a refractive index of the protective member 18 and/or the seal member 17, d is twice a cell size of the pixel 32, and A is a wavelength of the incident light Lin. According to Formula 1, as the diffraction order m increases, the diffraction angle θm of the reflected light Lrm also increases. For example, a diffraction angle θ2 of the second-order diffracted light Lr2 in FIG. 7 is larger than a diffraction angle θ1 of the first-order diffracted light Lr1, and a diffraction angle θ3 of the third-order diffracted light Lr3 is larger than the diffraction angle θ2 of the second-order diffracted light Lr2.

When the diffraction angle θm increases with the diffraction order m, the diffraction angle θm sometimes exceeds a critical angle θc of the protective member 18. For example, it is assumed that the diffraction angles θ1 and θ2 are smaller than the critical angle θc, and the diffraction angle θ3 and subsequent diffraction angles are greater than or equal to the critical angle θc. In this case, the reflected lights Lr1 and Lr2 travel from the protective member 18 to the outside air, and hardly generate ring flare. However, the diffracted reflected light after the reflected light Lr3 is totally reflected at a boundary between the protective member 18 and the air outside the protective member, and is re-incident on the on-chip lens 16 to generate ring flare RF. Note that the light source LS is located on the surface of the on-chip lens 16 of a certain pixel 32, and the ring flare RF is located on the surface of the on-chip lens 16 of another pixel 32. Therefore, the height levels of the incident positions of the light source LS and the reflected light Lr3 are substantially the same on the surface of the on-chip lens 16.

FIG. 8 is a schematic plan view illustrating the pixel sensor substrate 12 and the ring flare RF. It is assumed that the pixel region 21 is irradiated with light from a Z direction in plan view viewed from a light incident direction (Z direction). At this time, when the reflected light Lr3 that causes the ring flare RF enters the pixel region 21, the reflected light Lr3 is detected by the pixels 32 in the pixel region 21, and the ring flare RF is reflected in the image. On the other hand, when the reflected light Lr3 that causes the ring flare RF is not incident on the pixel region 21 but is outside the pixel region, the ring flare RF is not reflected in the image. That is, in order to prevent the ring flare RF from being reflected in the image, the reflected light Lr3 is only required to be emitted to the outside of the pixel region 21 without being incident on the pixel region 21 regardless of which position in the pixel region 21 is irradiated with light, that is, regardless of which position in the pixel region 21 the light source LS is located.

For example, the ring flare RF1 in FIG. 8 overlaps the pixel region 21, indicating that the reflected light Lr3 is incident on the pixel region 21. Therefore, the ring flare RF is reflected in the image. The ring flare RF2 in FIG. 8 does not overlap the pixel region 21, indicating that the reflected light Lr3 is not incident on the pixel region 21. Therefore, the ring flare RF is not reflected in the image.

In a plan view viewed from the Z direction, the ring flare RF does not appear in the image if the distance is larger than a distance of the diagonal line L from any vertex of the pixel region 21 to the farthest vertex. For example, as illustrated in FIG. 8, in a case where the pixel region 21 is substantially quadrangular and the light source LS is at one vertex of the pixel region 21, a radius of the ring flare RF may be larger than a diagonal line L of the pixel region 21, such as RF2.

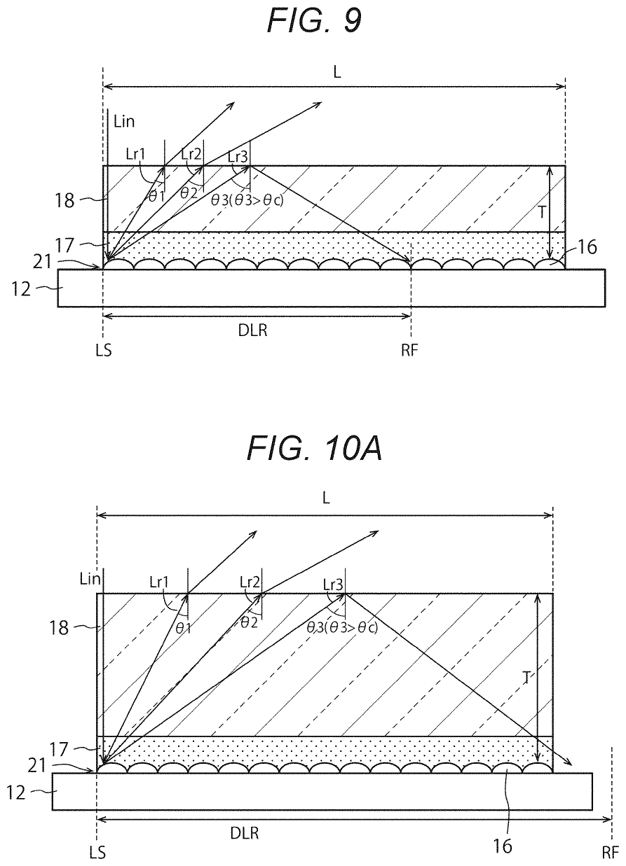

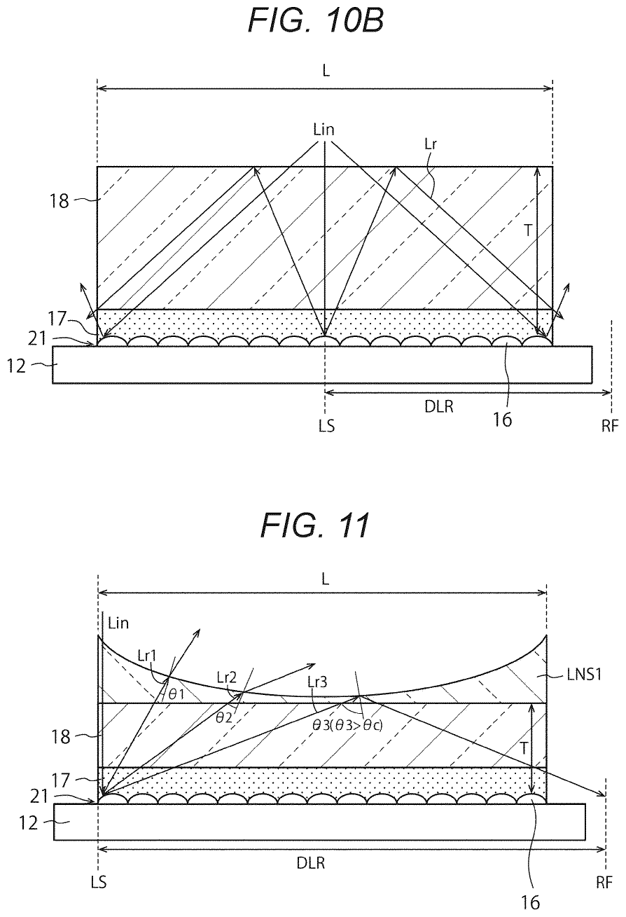

FIGS. 9, 10A, and 10B are schematic cross-sectional views taken along a direction of the diagonal line L of the pixel region 21 in FIG. 8. FIG. 9 illustrates the light source LS at one end (corner) of the pixel region 21. The reflected lights Lr1 to Lrm are incident on the surface of the protective member 18 at diffraction angles θ1 to θm. Note that, in FIG. 9, high order diffracted light having the diffraction order m of 4 or more is not illustrated. Furthermore, in the present specification and the drawings, the re-incident position of the reflected light Lr3 that causes the ring flare RF may also be referred to as ring flare RF.

Here, in order to make the distance DLR from the light source LS to the ring flare RF larger than the diagonal line L of the pixel region 21, the thicknesses T of the protective member 18 and the seal member 17 should just satisfy Formula 2. Note that θc is a critical angle of the reflected light Lr from the protective member 18 to the outside (air).

T≥L/2/tan θc (Formula 2)

In FIG. 9, the thicknesses T of the protective member 18 and the seal member 17 do not satisfy Formula 2, and the distance DLR is smaller than the diagonal line L of the pixel region 21. Therefore, the ring flare RF enters the pixel region 21 and is reflected in the image.

On the other hand, the thicknesses T of the protective member 18 and the seal member 17 illustrated in FIG. 10A are thicker than those illustrated in FIG. 9. The thicknesses T of the protective member 18 and the seal member 17 in FIG. 10A satisfy Formula 2. In this case, the distance DLR is larger than the diagonal line L of the pixel region 21, and the ring flare RF exits to the outside of the pixel region 21. As a result, it is possible to suppress the ring flare RF from being reflected in the image. Of course, in this case, ring flare (not illustrated) caused by the reflected light having the diffraction order m of 4 or more also appears outside the pixel region 21. Therefore, it is possible to suppress the ring flare RF caused by the high order diffracted reflected light after the reflected light Lr3 from being reflected in the image. That is, according to the present embodiment, since the thicknesses T of the protective member 18 and the seal member 17 satisfy Formula 2, the ring flare of all the reflected light having the diffraction angle larger than or equal to the critical angle θc exits to the outside of the pixel region 21. As a result, it is possible to suppress the ring flare RF from being reflected in the image and to suppress the influence of the ring flare RF.

As a specific example, in a case where the protective member 18 and the seal member 17 are glass, the critical angle θc of light from glass to air is about 41.5 degrees. Moreover, assuming that the distance of the diagonal line L of the pixel region 21 is 5 mm, the thicknesses T of the protective member 18 and the seal member 17 should be about 2.8 mm or more from Formula 2.

Note that, in a case where the pixel region 21 includes dummy pixels, the diagonal line L may be a diagonal line of effective pixels of the pixel region 21. On the other hand, the diagonal line L may be a diagonal line including both the effective pixels and the dummy pixels in the pixel region 21. Furthermore, in a case where the pixel region 21 is a polygon, L should be the maximum value of the distance between vertices.

As described above, according to the present embodiment, by setting the thicknesses T of the protective member 18 and the seal member 17 to satisfy Formula 2, the distance DLR from the light source LS to the ring flare RF can be made larger than the diagonal line L of the pixel region 21. As a result, it is possible to suppress the ring flare RF from being reflected in the image.

In the present embodiment, one protective member 18 may be thickened, or a plurality of the protective members 18 may be laminated to increase the overall thickness. Note that increasing the thicknesses T of the protective member 18 and the seal member 17 is against reduction in height (downsizing) of the imaging device. Therefore, an upper limit of the thicknesses T of the protective member 18 and the seal member 17 is determined according to an allowable range of the thickness of the imaging device.

The above-described embodiment described with reference to FIG. 10A is established in a case where the light source of the incident light Lin is not condensed so much, and the incident light Lin enters the pixel region 21 substantially in parallel.

On the other hand, FIG. 10B illustrates a state in which the incident light Lin is condensed by a lens (not illustrated) or the like. In a case where the incident light Lin is condensed, the incident light Lin radially enters the pixel region 21 from a point immediately above substantially a center of the pixel region 21. Therefore, the incident light Lin itself is obliquely incident on an end portion of the pixel region 21. Therefore, the reflected light having the end portion of the pixel region 21 as the light source LS is reflected to the outside of the pixel region 21 and does not generate ring flare. On the other hand, in a central portion of the pixel region 21, the incident light Lin is incident substantially perpendicularly from the Z direction. In this case, reflected light having the central portion of the pixel region 21 as the light source LS can generate the ring flare RF. In this case, in order to make the distance DLR from the light source LS to the ring flare RF larger than the distance L/2 from the central portion to the end portion of the pixel region 21, the thicknesses T of the protective member 18 and the seal member 17 should just satisfy Formula 3.

T≥L/4/tan θc (Formula 3)

When the thicknesses T of the protective member 18 and the seal member 17 satisfy Formula 3, the ring flare of all the reflected light having the diffraction angle larger than or equal to the critical angle θc exits to the outside of the pixel region 21. As a result, even in the case of condensing the incident light Lin, it is possible to suppress the reflection of the ring flare RF in the image and to suppress the influence of the ring flare RF.

### Second Embodiment

FIG. 11 is a schematic cross-sectional view illustrating a configuration example of a solid-state imaging device according to a second embodiment. FIG. 11 corresponds to a schematic cross section along a direction of the diagonal line L of the pixel region 21 in FIG. 8.

According to the second embodiment, a concave lens LNS1 is provided on the protective member 18 of the pixel region 21. For the concave lens LNS1, for example, a transparent material such as glass (SiO₂), nitride (SiN), sapphire (Al₂O₃), or resin is used. Low-order diffracted reflected light (for example, Lr1 and L2) reaches a surface of the concave lens LNS1 that is relatively closer to the light source LS than the centers of the pixel region 21 and the concave lens LNS1. In this case, diffraction angles θ1 and θ2 of the low-order reflected lights Lr1 and L2 are smaller than the diffraction angles θ1 and θ2 of the above-described first embodiment due to the curved surface of the concave lens LNS1. Therefore, the diffraction angles θ1 and θ2 of the low-order reflected lights Lr1 and L2 hardly exceed the critical angle θc, and easily pass through the surface of the concave lens LNS1.

On the other hand, high-order reflected light (for example, Lr3) reaches the surface of the concave lens LNS1 farther from the light source LS than the centers of the pixel region 21 and the concave lens LNS1. In this case, a diffraction angle θ3 of the high-order reflected light Lr3 is conversely larger than the diffraction angle θ3 of the first embodiment due to the curved surface of the concave lens LNS1. Therefore, the diffraction angle θ3 easily exceeds the critical angle θc, and the high-order reflected light Lr3 is easily emitted to the outside of the pixel region 21 before reaching the on-chip lens 16. That is, the ring flare RF is formed outside the pixel region 21.

As described above, by providing the concave lens LNS1 on the protective member 18, the low-order reflected light reaching the surface of the concave lens LNS1 closer to the light source LS than the center of the concave lens LNS1 hardly exceeds the critical angle θc. Conversely, high-order reflected light reaching the surface of the concave lens LNS1 farther from the light source LS than the center of the concave lens LNS1 is emitted to the outside of the pixel region 21. As a result, it is possible to suppress the occurrence of the ring flare RF while maintaining the thicknesses T of the protective member 18 and the seal member 17 or without making the thicknesses T too large. Alternatively, the distance DLR can be made larger than the diagonal line L of the pixel region 21, and the ring flare RF can be suppressed from being reflected in the image.

The other configurations of the second embodiment may be similar to the corresponding configurations of the first embodiment. As a result, the second embodiment can obtain the effect of the first embodiment.

### Third Embodiment

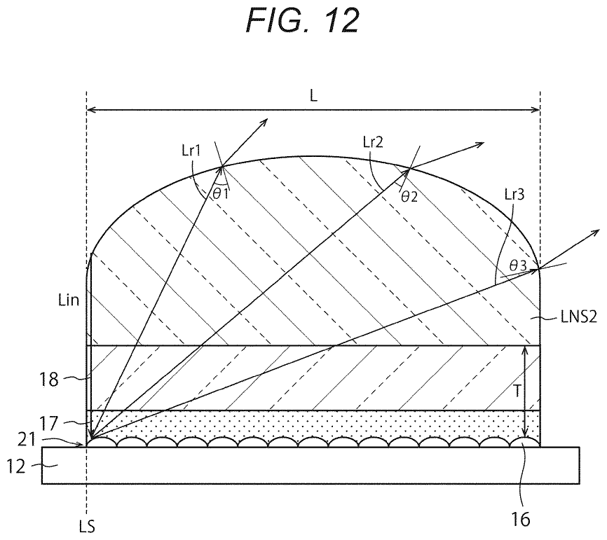

FIG. 12 is a schematic cross-sectional view illustrating a configuration example of a solid-state imaging device according to a third embodiment. FIG. 12 corresponds to a schematic cross section along the direction of the diagonal line L of the pixel region 21 in FIG. 8.

According to the third embodiment, a convex lens LNS2 is provided on the protective member 18 of the pixel region 21. For the convex lens LNS2, for example, a transparent material such as glass (SiO₂), nitride (SiN), sapphire (Al₂O₃), or resin is used. Due to a curved surface of the convex lens LNS2, diffraction angles θ1 to θm of the diffracted reflected lights Lr1 to Lrm are smaller than the diffraction angles θ1 to θm of the first embodiment. Therefore, the diffraction angles θ1 to θm hardly exceed the critical angle θc.

The condition that the diffraction angles θ1 to θm do not exceed the critical angle θc is expressed by Formula 3.

12.113×e^{0.92782×L/R}≤θc (Formula 3)

Note that Formula 3 illustrates a case where the convex lens LNS2 includes glass. R is a radius of curvature of the convex lens LNS2.

As described above, by providing the convex lens LNS2 on the protective member 18, it is possible to suppress the occurrence of the ring flare RF while maintaining the thicknesses T of the protective member 18 and the seal member 17 or without increasing the thicknesses T too much. As a result, the ring flare RF can be suppressed from being reflected in the image.

The other configurations of the third embodiment may be similar to the corresponding configurations of the first embodiment. As a result, the third embodiment can obtain the effect of the first embodiment.

### Fourth Embodiment

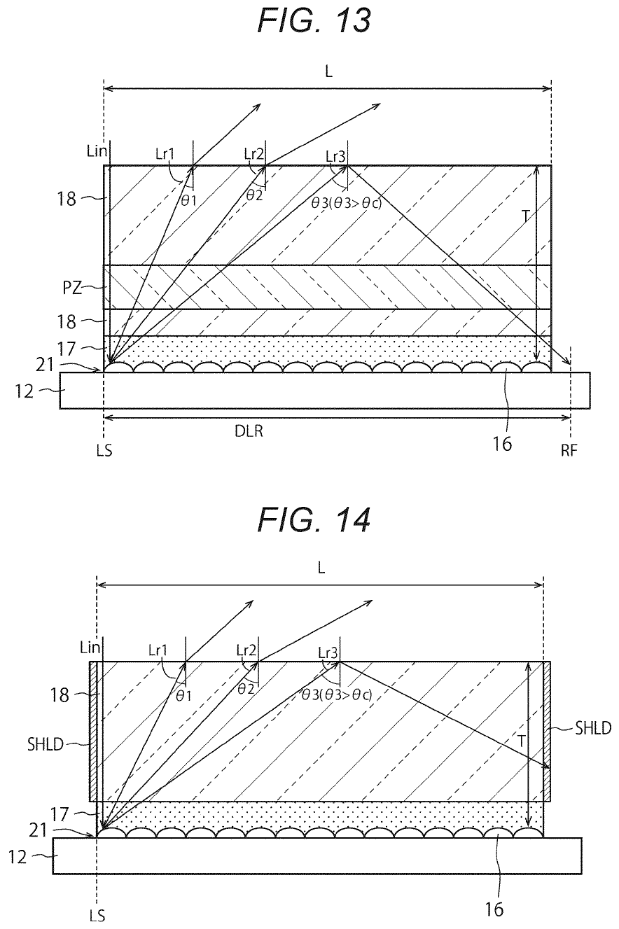

FIG. 13 is a schematic cross-sectional view illustrating a configuration example of a solid-state imaging device according to a fourth embodiment. FIG. 13 corresponds to a schematic cross section along the direction of the diagonal line L of the pixel region 21 in FIG. 8.

According to the fourth embodiment, a piezoelectric element PZ is provided as an example of an actuator under the protective member 18 or in the protective member 18. For the piezoelectric element PZ, for example, a transparent piezoelectric material such as PbTiO₃ is used. The piezoelectric element PZ is supplied with power via a contact CNT by the control circuit 38 in FIG. 3, for example, and a thickness thereof changes. As the thickness of the piezoelectric element PZ changes, the thicknesses T of the protective member 18 and the seal member 17 change. By controlling the thicknesses T of the protective member 18 and the seal member 17, the occurrence position of the ring flare RF can be controlled.

The other configurations of the fourth embodiment may be similar to the corresponding configurations of the first embodiment. As a result, the fourth embodiment can obtain the effect of the first embodiment.

### Fifth Embodiment

FIG. 14 is a schematic cross-sectional view illustrating a configuration example of a solid-state imaging device according to a fifth embodiment. FIG. 14 corresponds to a schematic cross section along the direction of the diagonal line L of the pixel region 21 in FIG. 8.

According to the fifth embodiment, a light absorbing film SHLD is provided on a side surface of the protective member 18. As the light absorbing film SHLD, for example, a black color filter (resin), a metal (for example, nickel, copper, carbon steel) having a high light absorption rate, or the like is used. The light absorbing film SHLD can prevent totally reflected light Lr3 from being emitted from the side surface of the protective member 18 to the outside, for example. As a result, it is possible to prevent the reflected light Lr3 from adversely affecting other devices (not illustrated) outside. Furthermore, since the light absorbing film SHLD absorbs the reflected light Lr3, the reflected light does not enter the pixel 32 in the pixel region 21. Thus, in the fifth embodiment, the occurrence of the ring flare RF can be suppressed.

Other configurations of the fifth embodiment may be similar to the corresponding configurations of the first embodiment. As a result, the fifth embodiment can obtain similar effects to those of the first embodiment.

Note that the light absorbing film SHLD may be provided on the entire side surface of the protective member 18, or may be partially provided on an upper portion or a lower portion of the side surface.

### Sixth Embodiment

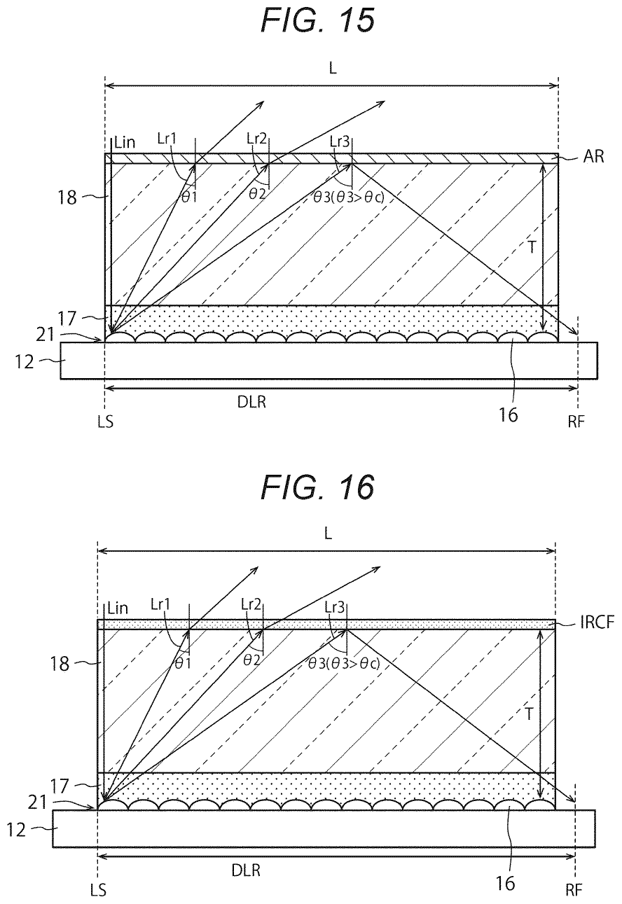

FIG. 15 is a schematic cross-sectional view illustrating a configuration example of a solid-state imaging device according to a sixth embodiment. FIG. 15 corresponds to a schematic cross section along the direction of the diagonal line L of the pixel region 21 in FIG. 8.

According to the sixth embodiment, an antireflection film AR is provided on an upper surface of the protective member 18. For the antireflection film AR, for example, a silicon oxide film, a silicon nitride film, TiO₂, MgF₂, Al₂O₃, CeF₃, ZrO₂, CeO₂, ZnS, or a laminated film thereof is used. The antireflection film AR suppresses reflection of the incident light Lin on the surface of the protective member 18 and makes the reflected lights Lr1 to Lrm less likely to be reflected on the surface of the protective member 18. Therefore, the sensitivity of the solid-state imaging device 1 can be improved, and the reflected lights Lr1 to Lrm can be suppressed from re-entering the pixel region 21. As a result, it is possible to prevent the reflected lights Lr1 to Lrm from adversely affecting other devices (not illustrated) outside. Furthermore, the occurrence of the ring flare RF can be suppressed.

The other configurations of the sixth embodiment may be similar to the corresponding configurations of the first embodiment. As a result, the sixth embodiment can obtain similar effects to those of the first embodiment.

The solid-state imaging device 1 according to the sixth embodiment can be used for applications such as a high-sensitivity camera.

### Seventh Embodiment

FIG. 16 is a schematic cross-sectional view illustrating a configuration example of a solid-state imaging device according to a seventh embodiment. FIG. 16 corresponds to a schematic cross section along the direction of the diagonal line L of the pixel region 21 in FIG. 8.

According to the seventh embodiment, an infrared cut filter IRCF is provided on the upper surface of the protective member 18. For the infrared cut filter IRCF, for example, a silicon oxide film, a silicon nitride film, TiO₂, MgF₂, Al₂O₃, CeF₃, ZrO₂, CeO₂, ZnS, or a laminated film thereof, infrared absorption glass, or the like is used as antireflection design. The infrared cut filter IRCF cuts off an infrared component from the incident light Lin and allows other visible light components to pass therethrough. As a result, the solid-state imaging device 1 can generate an image based on visible light.

The other configurations of the seventh embodiment may be similar to the corresponding configurations of the first embodiment. As a result, the seventh embodiment can obtain similar effects to those of the first embodiment.

The solid-state imaging device 1 according to the seventh embodiment can be used for applications such as a monitoring camera.

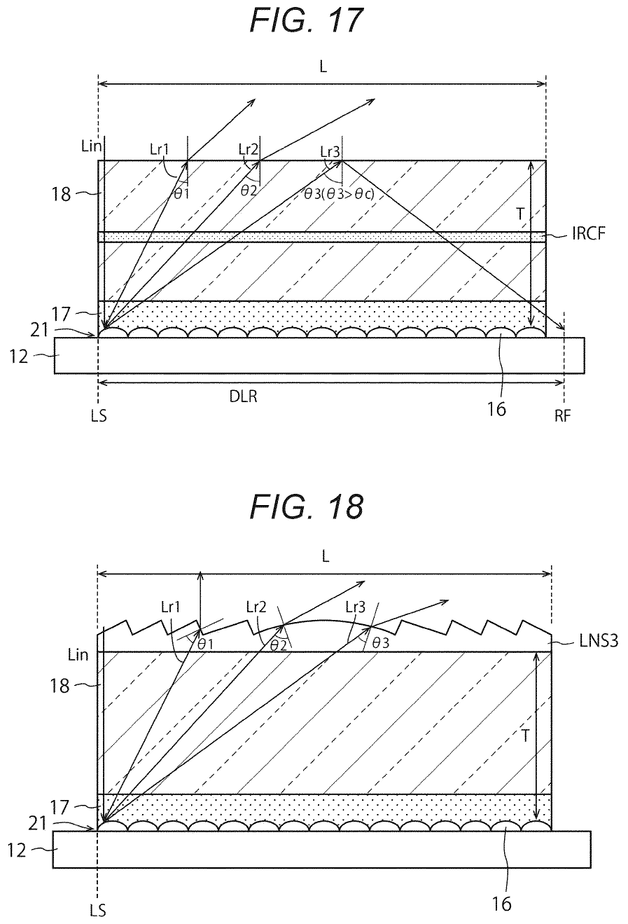

FIG. 17 is a schematic cross-sectional view illustrating a configuration example of a solid-state imaging device according to a modification example of the sixth embodiment. In the modification example of FIG. 17, an infrared cut filter IRCF is provided in an intermediate portion in the protective member 18. As described above, even if the infrared cut filter IRCF is provided in the intermediate portion in the protective member 18, the effect of the present embodiment is not lost.

### Eighth Embodiment

FIG. 18 is a schematic cross-sectional view illustrating a configuration example of a solid-state imaging device according to an eighth embodiment. FIG. 18 corresponds to a schematic cross section along the direction of the diagonal line L of the pixel region 21 in FIG. 8.

According to the eighth embodiment, a Fresnel lens LNS3 is provided on the upper surface of the protective member 18. For the Fresnel lens LNS3, for example, a transparent material such as glass (SiO₂), nitride (SiN), sapphire (Al₂O₃), or resin is used. Similarly to the convex lens LNS2, the Fresnel lens LNS3 reduces diffraction angles θ1 to θm of the diffracted reflected lights Lr1 to Lrm by a curved surface. Therefore, the diffraction angles θ1 to θm hardly exceed the critical angle θc. By using the Fresnel lens LNS3, the solid-state imaging device 1 can have a height lower than that of the third embodiment. Other configurations of the eighth embodiment may be similar to the corresponding configurations of the third embodiment. As a result, the eighth embodiment can obtain the effect of the third embodiment.

Although not illustrated, the Fresnel lens LNS3 may have characteristics similar to those of the concave lens LNS1. As a result, the eighth embodiment can obtain similar effects to those of the second embodiment.

### Ninth Embodiment

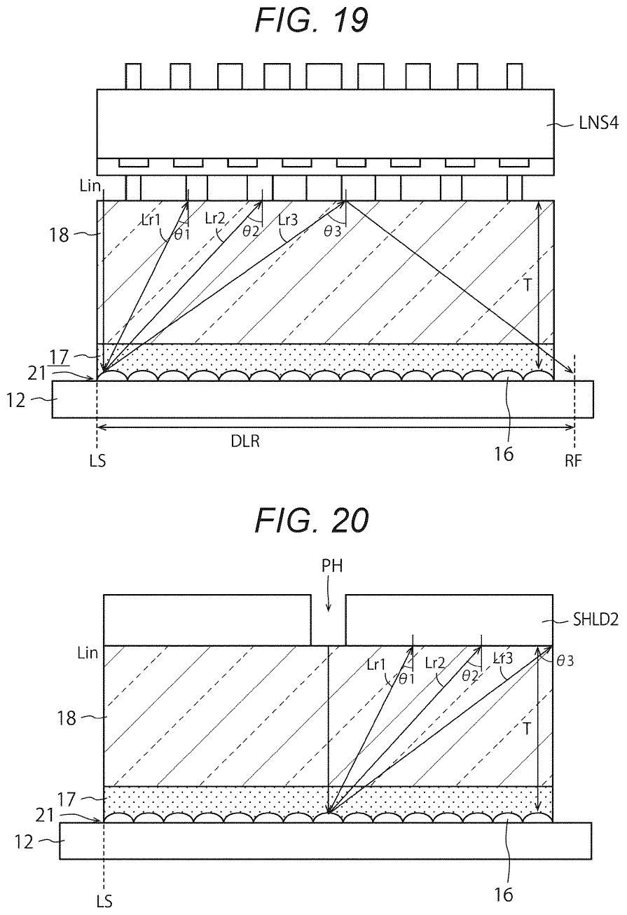

FIG. 19 is a schematic cross-sectional view illustrating a configuration example of a solid-state imaging device according to a ninth embodiment. FIG. 19 corresponds to a schematic cross section along the direction of the diagonal line L of the pixel region 21 in FIG. 8.

According to the ninth embodiment, a metalens LNS4 is provided on the upper surface of the protective member 18. The metalens LNS4 can set diffraction angles θ1 to θm of the diffracted reflected lights Lr1 to Lrm to be smaller than the critical angle θc, or can set the ring flare RF to the outside of the pixel region 21. That is, the metalens LNS4 can function like the convex lens LNS2 or the concave lens LNS1. As a result, the ninth embodiment can obtain the similar effects to those of the second or third embodiment.

### Tenth Embodiment

FIG. 20 is a schematic cross-sectional view illustrating a configuration example of a solid-state imaging device according to a tenth embodiment. FIG. 20 corresponds to a schematic cross section along the direction of the diagonal line L of the pixel region 21 in FIG. 8.

According to the tenth embodiment, a light shielding film SHLD2 having a pinhole PH is provided on the upper surface of the protective member 18. For example, a light shielding metal such as nickel or copper is used for the light shielding film SHLD2. The pinhole PH is provided at a center of the light shielding film SHLD2, and the incident light Lin is incident only from the pinhole PH. The pinhole PH is provided substantially at the center of the light shielding film SHLD2. Thus, diffraction angles θ1 to θm of the diffracted reflected lights Lr1 to Lrm can be made smaller than the critical angle θc. Accordingly, in the tenth embodiment, the occurrence of the ring flare RF can be suppressed. Other configurations of the tenth embodiment may be similar to the corresponding configurations of the first embodiment.

### (Relationship Between Size of Pixel 32 and Thickness of Protective Member 18)

When the size of the pixel 32 illustrated in FIG. 9 or FIG. 10A changes, the size of the on-chip lens 16 changes. Therefore, the appropriate thicknesses T of the protective member 18 and the seal member 17 in which the ring flare RF is not reflected in the image vary depending on the size of the pixel 32. For example, when the size (width) of the pixel 32 viewed from the Z direction is a first width W1, in a case where the thicknesses of the protective member 18 and the seal member 17 are a first thickness T1 or more, the ring flare RF is not reflected in the image. In this case, when the width of the pixel 32 is a second width W2 (W2<W1) smaller than the first width W1, the thicknesses of the protective member 18 and the seal member 17 are preferably greater than or equal to a second thickness T2 (T2>T1) that is greater than the first thickness T1. This is because as the size of the pixel 32 decreases, the on-chip lens 16 also decreases, and the diffraction angles θ1 to θm of the reflected lights Lr1 to Lrm increase.

For example, in a case where the second width W2 is ½ of the first width W1, each of the diffraction angles θ1 to θm is about twice, and the second thickness T2 is preferably about twice or more the first thickness T1. For example, in a case where the size of the pixel 32 (the length of the diagonal line L) is about 2 μm, the diffraction angle θ3 is about 20 degrees. On the other hand, in a case where the size of the pixel 32 (the length of the diagonal line L) is about 1 μm, the diffraction angle θ3 is about 40 degrees. In this case, the thickness T2 should be about twice or more the thickness T1. That is, when the size of the pixel 32 decreases, the diffraction angles θ1 to θm of the reflected lights Lr1 to Lrm increase and easily exceed the critical angle θc. Therefore, it is preferable to increase the thickness of the protective member 18 as the size of the pixel 32 is smaller. As a result, it is possible to effectively prevent the ring flare RF from being reflected in the image.

### Eleventh Embodiment

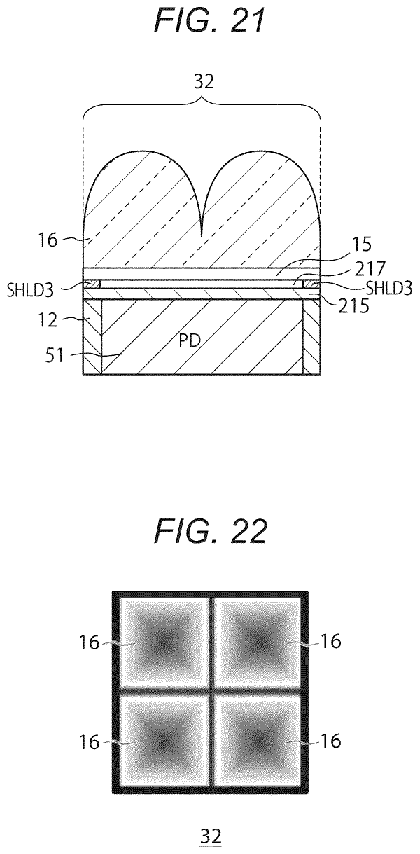

FIG. 21 is a schematic cross-sectional view illustrating a configuration example of a solid-state imaging device according to an eleventh embodiment. FIG. 22 is a schematic plan view illustrating a configuration example of the solid-state imaging device according to the eleventh embodiment. FIGS. 21 and 22 illustrate a schematic cross-section and a schematic plane of one pixel 32.

In the eleventh embodiment, a plurality of on-chip lenses 16 is provided for each of the pixels 32. For example, four identical on-chip lenses 16 are arranged substantially evenly for one pixel 32. That is, as illustrated in FIG. 22, the four on-chip lenses 16 are arranged in 2 rows and 2 columns on one pixel 32.

As described above, since the on-chip lens 16 and the pixel 32 do not correspond to each other on a one-to-one basis, and the plurality of on-chip lenses 16 is substantially evenly arranged on one pixel 32, the reflected lights Lr1 to Lrm are dispersed. As a result, the ring flare RF is also dispersed, and a contour of the ring flare RF reflected in the image can be blurred.

The other configuration of the eleventh embodiment may be similar to the configuration of any one of the above-described embodiments. As a result, the eleventh embodiment can also obtain the effects of other embodiments. Note that a protective film 215 is formed on the pixel sensor substrate 12 and the photodiode 51. For the protective film 215, for example, an insulating material such as a silicon oxide film is used. A light shielding film SHLD3 provided between the adjacent pixels 32 is provided on the protective film 215. For example, a light shielding metal such as nickel or copper is used for the light shielding film SHLD3. The light shielding film SHLD3 suppresses leakage of light into the adjacent pixels 32. A planarization film 217 for planarizing a region where the color filter 15 is to be formed is formed on the protective film 215 and the light shielding film SHLD3. For the planarization film 217, for example, an insulating material such as a silicon oxide film is used. The color filter 15 is formed on the planarization film 217. The color filter 15 is provided with a plurality of color filters for each pixel, and the colors of the color filters are arranged in a Bayer array, for example.

### Twelfth Embodiment

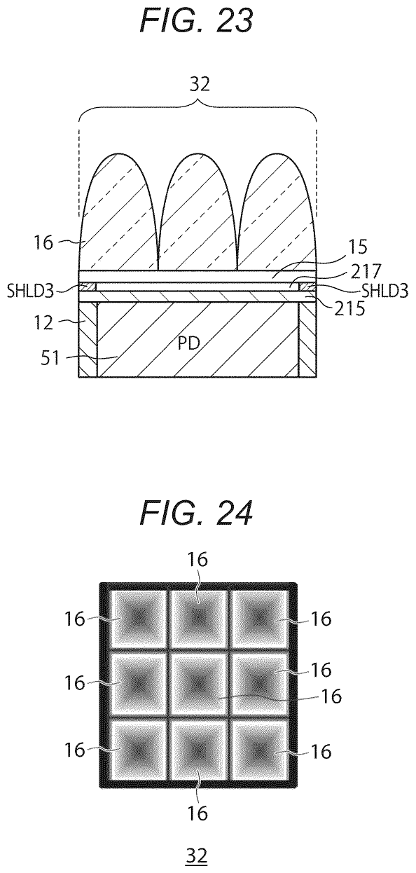

FIG. 23 is a schematic cross-sectional view illustrating a configuration example of a solid-state imaging device according to a twelfth embodiment. FIG. 24 is a schematic plan view illustrating a configuration example of the solid-state imaging device according to the twelfth embodiment. FIGS. 23 and 24 illustrate a schematic cross-section and a schematic plane of one pixel 32.

In the twelfth embodiment, nine identical on-chip lenses 16 are arranged substantially evenly for one pixel 32. That is, as illustrated in FIG. 24, nine on-chip lenses 16 are arranged in 3 rows and 3 columns on one pixel 32.

In this manner, since the plurality of on-chip lenses 16 is substantially evenly arranged on one pixel 32, the reflected lights Lr1 to Lrm are dispersed. As a result, the ring flare RF is also dispersed, and a contour of the ring flare RF reflected in the image can be blurred.

The other configuration of the twelfth embodiment may be similar to the configuration of any one of the above-described embodiments. As a result, the effects of other embodiments can also be obtained in the twelfth embodiment.

Moreover, although not illustrated, the on-chip lenses 16 of k rows and k columns (k is an integer of 4 or more) may be arranged substantially evenly on one pixel 32. By increasing k, the reflected lights Lr1 to Lrm are further dispersed, and a contour of the ring flare RF reflected in the image can be further blurred.

### Thirteenth Embodiment

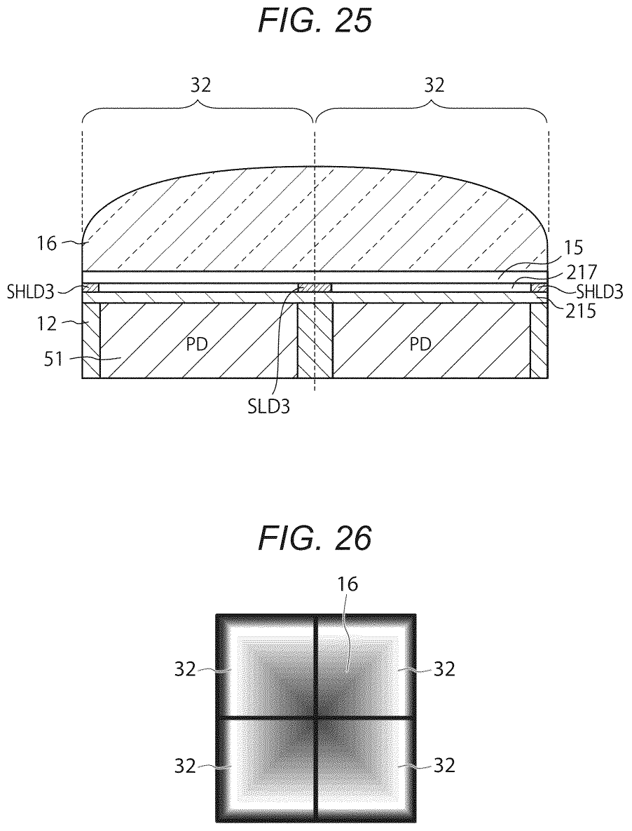

FIG. 25 is a schematic cross-sectional view illustrating a configuration example of a solid-state imaging device according to a thirteenth embodiment. FIG. 26 is a schematic plan view illustrating a configuration example of the solid-state imaging device according to the thirteenth embodiment. FIGS. 25 and 26 illustrate a schematic cross-section and a schematic plane of one pixel 32.

In the thirteenth embodiment, one on-chip lens 16 is provided for a plurality of pixels 32. For example, as illustrated in FIG. 26, one on-chip lens 16 is disposed on four pixels 32 of 2 rows and 2 columns.

As described above, since the one on-chip lens 16 is disposed on the plurality of pixels 32, diffraction angles θ1 to θm of the diffracted reflected lights Lr1 to Lrm are relaxed (reduced), and the reflected light exceeding the critical angle θc is reduced. For example, in a case where one on-chip lens 16 is disposed on the four pixels 32, the reflected light exceeding the critical angle θc becomes ¼. As a result, the ring flare RF can be suppressed from being reflected in the image.

The other configuration of the thirteenth embodiment may be similar to the configuration of any one of the above-described embodiments. As a result, the effects of other embodiments can also be obtained in the thirteenth embodiment.

Moreover, although not illustrated, one on-chip lens 16 may be further disposed on the pixel 32 of k rows and k columns (k is an integer of 3 or more). By increasing k, the reflected light exceeding the critical angle θc is further reduced, and the ring flare RF can be further suppressed from being reflected in the image.

### Fourteenth Embodiment

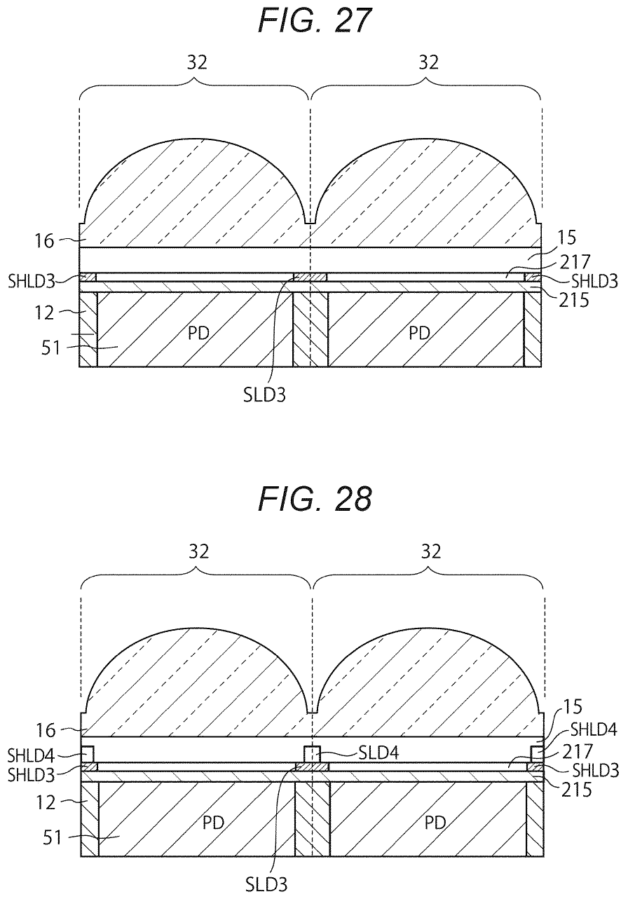

FIG. 27 is a schematic cross-sectional view illustrating a configuration example of a solid-state imaging device according to a fourteenth embodiment.

In the fourteenth embodiment, a light shielding film SHLD3 is provided in the color filter 15 provided between the pixel 32 and the on-chip lens 16. For example, a light shielding metal such as nickel or copper is used for the light shielding film SHLD3. The light shielding film SHLD3 is provided between the adjacent pixels 32, and can suppress light leakage (crosstalk) between the adjacent pixels 32.

The other configuration of the fourteenth embodiment may be similar to the configuration of any one of the above-described embodiments. As a result, the fourteenth embodiment can also obtain the effects of other embodiments.

### Fifteenth Embodiment

FIG. 28 is a schematic cross-sectional view illustrating a configuration example of a solid-state imaging device according to a fifteenth embodiment.

In the fifteenth embodiment, a light shielding film SHLD4 is further provided on the light shielding film SHLD3 in the color filter 15. For example, a light shielding metal such as nickel or copper is used for the light shielding film SHLD4. The light shielding film SHLD4 is provided above between the adjacent pixels 32, and can further suppress light leakage (crosstalk) between the adjacent pixels 32 together with the light shielding film SHLD3.

The other configuration of the fifteenth embodiment may be similar to the configuration of any one of the above-described embodiments. As a result, the fifteenth embodiment can also obtain the effects of other embodiments.

### Modification Examples

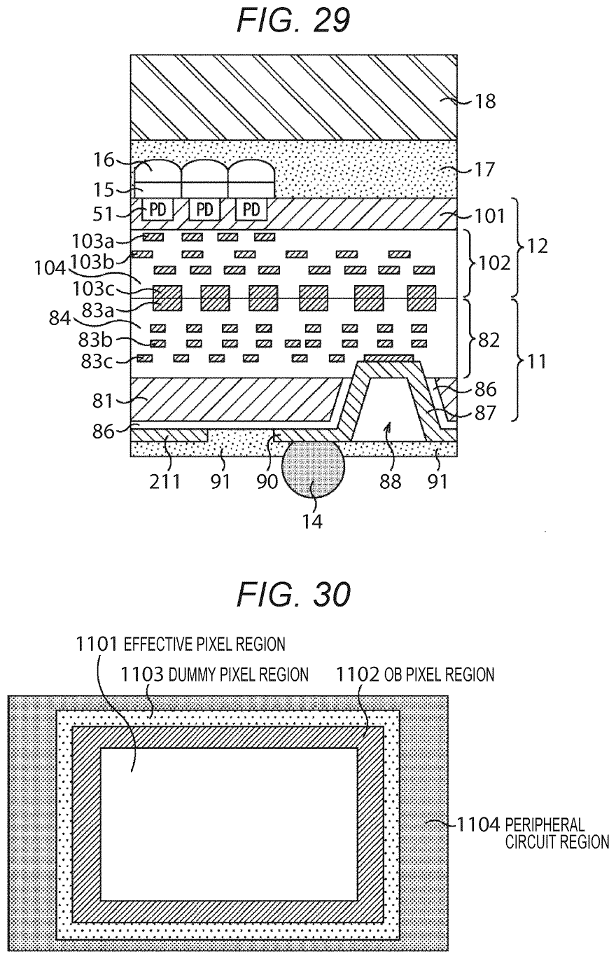

FIG. 29 is a schematic cross-sectional view illustrating a configuration example of a solid-state imaging device 1 according to a modification example.

In the modification example of FIG. 29, a method of connecting the lower substrate (logic substrate) 11 and the upper substrate (pixel sensor substrate) 12 is different from the basic structure of FIG. 5.

That is, in the basic structure of FIG. 5, the logic substrate 11 and the pixel sensor substrate 12 are connected by using two through vias of the through silicon via 151 and the through chip via 152, whereas in the present modification example, the logic substrate 11 and the pixel sensor substrate 12 are connected by metal bonding (Cu—Cu bonding) of the uppermost wiring layer 83a in the multilayer wiring layer 82 of the logic substrate 11 and the lowermost wiring layer 103c in the multilayer wiring layer 102 of the pixel sensor substrate 12.

In the present modification example, a connection method with the solder ball 14 on the lower side of the solid-state imaging device 1 is similar to the basic structure of FIG. 5. That is, the through silicon via 88 is connected to the lowermost wiring layer 83c of the logic substrate 11, and thereby, the solder ball 14 is connected to the wiring layer 83 and the wiring layer 103 in the laminated substrate 13.

On the other hand, the present modification example is different from the basic structure of FIG. 5 in that a dummy wiring 211, which is not electrically connected anywhere, is formed on the lower surface side of the silicon substrate 81 in the same layer as the rewiring 90 to which the solder balls 14 are connected and includes the same wiring material as the rewiring 90.

The dummy wiring 211 is for reducing the influence of unevenness at the time of metal bonding (Cu—Cu bonding) between the uppermost wiring layer 83a on the logic substrate 11 side and the lowermost wiring layer 103c on the pixel sensor substrate 12 side. That is, when the Cu—Cu bonding is performed, if the rewiring 90 is formed only in a partial region of the lower surface of the silicon substrate 81, unevenness occurs due to a difference in thickness due to the presence or absence of the rewiring 90. Therefore, by providing the dummy wiring 211, the influence of the unevenness can be reduced.

### (First Modification Example of Pixel Region 21)

FIG. 30 is a diagram illustrating a main configuration example of an imaging device to which the present technology is applied. An imaging element 100 is a back-illuminated CMOS image sensor. On a light irradiation surface of the imaging element 100, an effective pixel region 1101 is formed in a central portion, and an OB pixel region 1102 is formed so as to surround the periphery of the effective pixel region 1101. Furthermore, a dummy pixel region 1103 is formed so as to surround the periphery of the OB pixel region 1102, and a peripheral circuit 1104 in which a peripheral circuit is formed is formed outside the dummy pixel region.

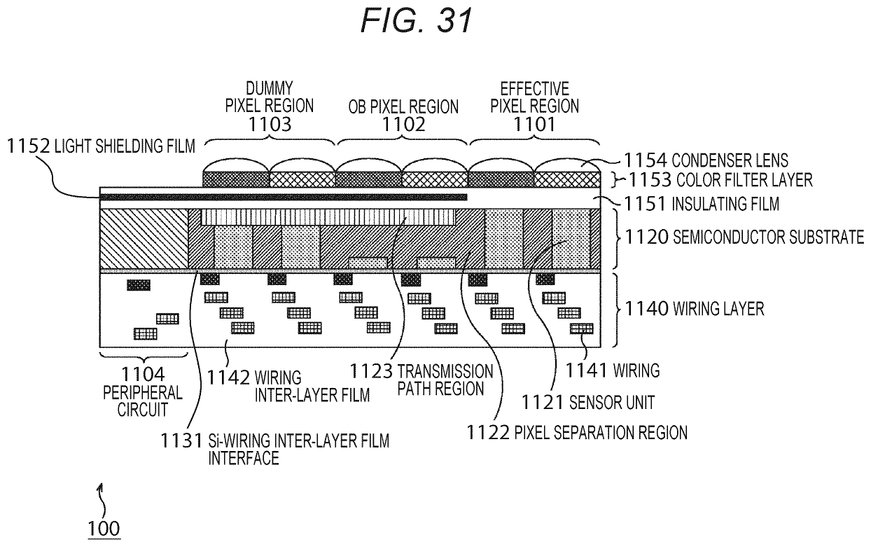

FIG. 31 is a cross-sectional view for explaining a configuration of each region of the imaging element 100. An upper side in the drawing is a light irradiation surface (back surface side). That is, light from a subject enters the imaging element 100 from a top to a bottom in the drawing.

The imaging element 100 has a multilayer structure with respect to a traveling direction of the incident light. That is, the light incident on the imaging element 100 travels so as to transmit each layer.

Note that, in FIG. 31, only configurations of some pixels (in the vicinity of the boundary of each region) of the effective pixel region 1101 to the dummy pixel region 1103 and configurations of a part of the peripheral circuit 1104 are illustrated.

In the effective pixel region 1101 to the dummy pixel region 1103, the sensor unit 1121, which is a photoelectric conversion element such as a photodiode, is formed for each pixel on the semiconductor substrate 1120 of the imaging element 100. A pixel separation region 1122 is formed between the sensor units 1121.

The configuration of each pixel of the effective pixel region 1101 to the dummy pixel region 1103 is basically similar. However, the effective pixel region 1101 photoelectrically converts the incident light and outputs a pixel signal for forming an image. Since the dummy pixel region 1103 is a region provided to stabilize the pixel characteristics of the effective pixel region 1101 and the OB pixel region 1102, the pixel output of this region is basically not used (not used as a dark output (black level) reference). Note that the dummy pixel region 1103 also plays a role of suppressing a shape change due to a difference between patterns from the OB pixel region 1102 to the peripheral circuit 1104 at the time of forming the color filter layer 1153 and the condenser lens 1154.

Furthermore, each pixel of the OB pixel region 1102 and the dummy pixel region 1103 is shielded by a light shielding film 1152 formed in the insulating film 1151 so that light does not enter from the pixel. Therefore, ideally, a pixel signal from the OB pixel region serves as a dark output (black level) reference. Actually, the pixel value may rise due to wraparound of light from the effective pixel region 1101 or the like, and thus the imaging element 100 is configured to suppress this influence.

For example, in order to lower the sensitivity, the sensor unit 1121 of each pixel of the OB pixel region 1102 is not formed up to a deep portion of the semiconductor substrate 1120 but is formed only in a shallow region on a front surface side.

Furthermore, in the semiconductor substrate 1120, a transmission path region 1123 serving as a path for electrons is formed from the OB pixel region 1102 to the dummy pixel region 1103 at a deep portion (back surface side) that does not intersect with the sensor unit 1121 of each pixel of the effective pixel region 1101.

On the front surface side of the semiconductor substrate 1120, a silicon (Si)-wiring inter-layer film interface 1131 and a wiring layer 1140 are laminated. In the wiring layer 1140, a plurality of layers of wirings 1141 and a wiring inter-layer film 1142 between the wirings 1141 including an insulating material are formed.

The insulating film 1151, the color filter layer 1153, and the condenser lens 1154 are laminated on the back surface side of the semiconductor substrate 1120. As described above, the light shielding film 1152 that shields light is formed in the insulating film 1151 of the OB pixel region 1102 and the dummy pixel region 1103. As a result, black level setting in an image and prevention of device adverse effects due to light incident on a peripheral circuit are realized.

In the peripheral circuit 1104, a read gate, a vertical charge transfer unit that transfers the read signal charge in the vertical direction, a horizontal charge transfer unit, and the like are formed.

The present technology may also be applied to the pixel region 21 according to the first modification example described above. The pixel region 21 may be only the effective pixel region 1101, but may further include an OB pixel region 1102 and/or a dummy pixel region 1103 in addition to the effective pixel region 1101.

### (Second Modification Example of Pixel Region 21)

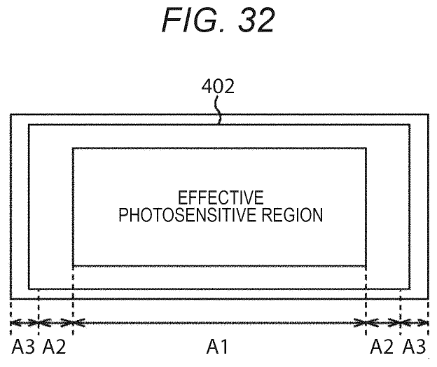

FIG. 32 is a schematic plan view of the configuration of a semiconductor package 200. The semiconductor package 200 is largely divided into an effective photosensitive region A1, an outside A2 of the effective photosensitive region, and a terminal portion A3.

The effective photosensitive region Al is a region in which pixels having photodiodes 214 provided on the surface of a silicon substrate 213 are arranged. The outside (external region) A2 of the effective photosensitive region is a region where no pixel including the photodiode 214 is arranged, and is a region provided around the effective photosensitive region A1. The terminal portion A3 is, for example, a region for cutting the semiconductor package 200 from the wafer, and is a region including an end portion (Hereinafter, referred to as a chip end.) of the semiconductor package 200. The terminal portion A3 is provided around the outside A2 of the effective photosensitive region.

Meanwhile, a microlens layer 220 is sandwiched between a first organic material layer 219 and a second organic material layer 222. In recent chip size packages (CSPs), a cavityless CSP is becoming widespread in order to achieve reduction in height and size. In the cavityless CSP, an inorganic material SiN having a high refractive index (high bending) is often used as a material of the microlens layer 220 in order to make a difference in refractive index between the low bending material resin (corresponding to the second organic material layer 222) filling the space and the microlens layer 220.

In such a structure, SiN constituting the microlens layer 220 has a high film stress, and the periphery of such a microlens layer 220 is surrounded by a resin as the second organic material layer 222. In such a state, the second organic material layer 222 around the microlens layer 220 is softened at high temperature to release the film stress, and there is a possibility that the lens of the microlens layer 220 is deformed. When deformation of the lens occurs, there is a possibility that image quality degradation such as shading and color unevenness occurs. Therefore, it is necessary to prevent such deformation of the lens.

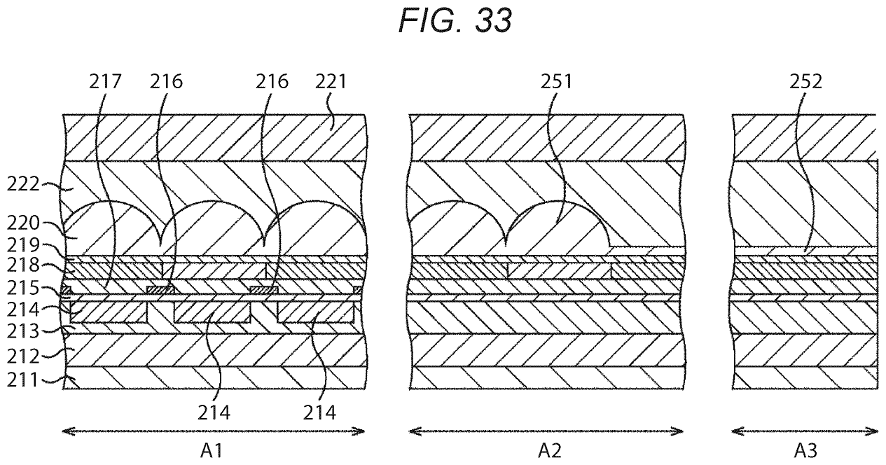

Therefore, as illustrated in FIG. 33, a dummy lens 251 is provided in a portion of the outside A2 of the effective photosensitive region. The dummy lens 251 includes the same material (inorganic material SiN (silicon nitride), and the like) as the microlens layer 220, and is formed to have the same size and shape as the lens of the microlens layer 220. In other words, it is not originally necessary to provide the microlens layer 220 in the outside A2 of the effective photosensitive region, but by extending the microlens layer 220 also to the outside A2 of the effective photosensitive region and providing the microlens layer as the dummy lens 251, deformation of the lens can be prevented.

Since such a dummy lens 251 can be formed at the time of forming the microlens layer 220, it is possible to form the dummy lens without increasing the number of steps.

In this manner, by configuring the structure having the same force as the force per unit area of the microlens layer 220 in the outside A2 of the effective pixel region with the same material (inorganic material) as the microlens layer 220, it is possible to balance the stress between the microlens layer 220 and the dummy lens 251.

The terminal portion A3 is provided with a flat film 302 as an extension from the dummy lens 251 from the outside A2 of the effective photosensitive region using the same material as that of the microlens layer 220 and the dummy lens 251 although having a shape different from that of the lens of the microlens layer 220. Note that the film 302 may not be the same material as the microlens layer or the dummy lens 251.

In this way, by providing the dummy lens 251, it is possible to balance the stress between the microlens layer 220 in the effective photosensitive region A1 and the dummy lens 251, and it is possible to prevent deformation from occurring in the microlens layer 220.

The present technology may also be applied to the pixel region 21 according to the second modification example described above.

The present technology may also be applied to the pixel region 21 according to the second modification example described above. The pixel region 21 may be only the following effective pixel region A1, but may further include the outside A2 of the effective photosensitive region and/or the terminal portion A3 in addition to the effective pixel region A1.

### (Application Example to Mobile Body)

The technology according to the present disclosure (the present technology) can be applied to various products. For example, the technology according to the present disclosure may be realized as a device equipped on any type of mobile bodies, such as an automobile, an electric car, a hybrid electric car, a motorcycle, a bicycle, personal mobility, an airplane, a drone, a ship, a robot, and the like.

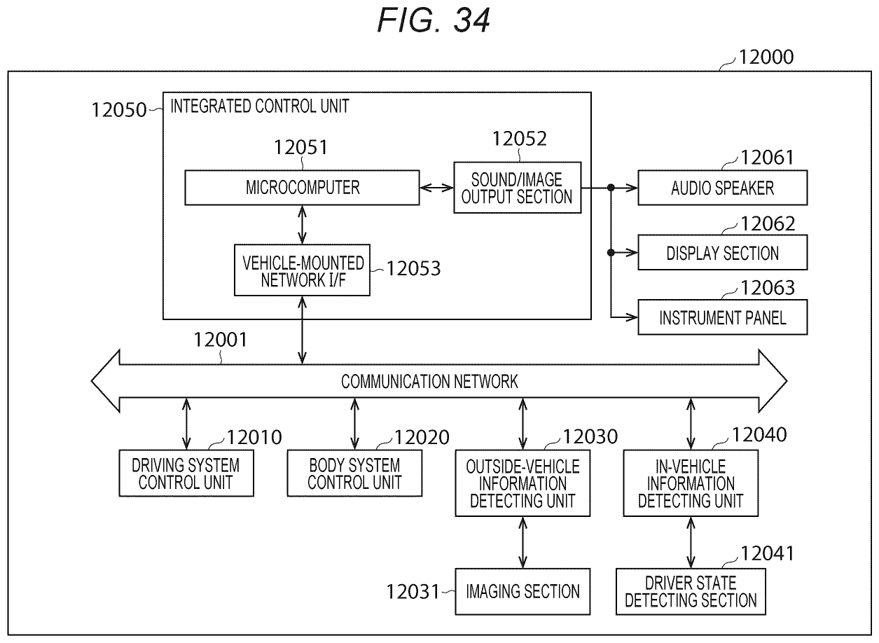

FIG. 34 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example of FIG. 34, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 34, an audio speaker 12061, a display section 12062, and an instrument panel 12063 are illustrated as the output device. The display section 12062 may, for example, include at least one of an on-board display and a head-up display.

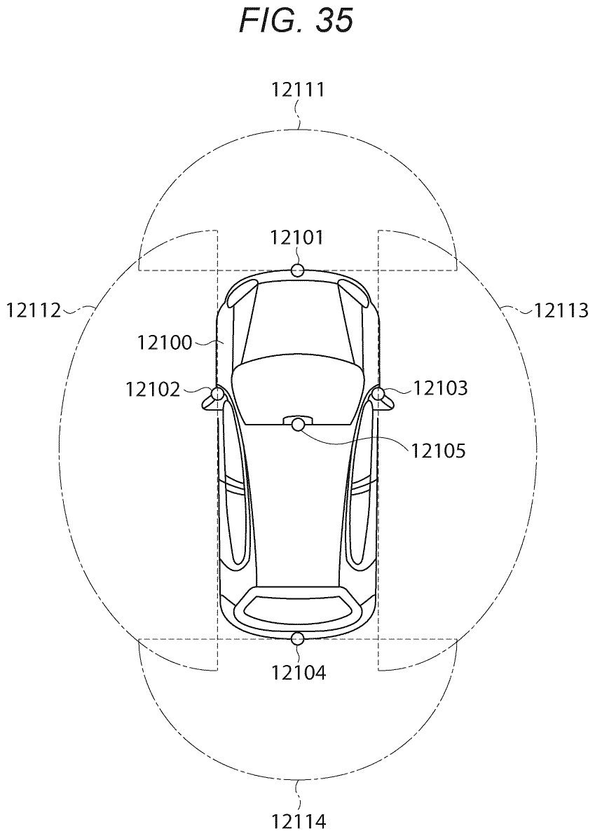

FIG. 35 illustrates an example of an installation position of the imaging section 12031.

In FIG. 35, imaging sections 12101, 12102, 12103, 12104, and 12105 are included as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 35 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied has been described above. The technology according to an embodiment of the present disclosure can be applied to, for example, the imaging section 12031 and the like among the configurations described above.

Note that the present technology can have the following configurations.
(1)

An imaging device including:
a pixel region in which a plurality of pixels that performs photoelectric conversion is arranged;
an on-chip lens provided on the pixel region;
a protective member provided on the on-chip lens; and
a resin layer that adheres between the on-chip lens and the protective member,
in which when a thickness of the resin layer and the protective member is T, a length of a diagonal line of the pixel region viewed from an incident direction of light is L, and a critical angle of the protective member is θc,

T≥L/2/tan θc (Formula 2)

T≥L/4/tan θc (Formula 3)

Formula 2 or 3 is satisfied.
(2)

The imaging device according to (1), in which
glass is used for the protective member, and
the critical angle θc is about 41.5°.
(3)

The imaging device according to (1) or (2), further including a concave lens provided on the protective member.
(4)

The imaging device according to (1) or (2), further including a convex lens provided on the protective member.
(5)

The imaging device according to (1) or (2), further including an actuator that is provided under the protective member or in the protective member and changes a thickness of the protective member.
(6)

The imaging device according to any one of (1) to (5), further including a light absorbing film provided on a side surface of the protective member.
(7)

The imaging device according to any one of (1) to (5), further including an antireflection film provided on the protective member.
(8)

The imaging device according to any one of (1) to (5), further including an infrared cut filter provided on the protective member or in the protective member.
(9)

The imaging device according to any one of (1) to (5), further including a Fresnel lens provided on the protective member.
(10)

The imaging device according to any one of (1) to (5), further including a metalens provided on the protective member.
(11)

The imaging device according to any one of (1) to (5), further including a light shielding film provided on the protective member and including a hole.
(12)

The imaging device according to any one of (1) to (11), in which the thickness T is greater than or equal to a first thickness T1 when a width of the pixel is a first width W1 in a plan view viewed from the incident direction, and
when the width of the pixel is a second width W2 (W2<W1) smaller than the first width, the thickness T is greater than or equal to a second thickness T2 (T2>T1) that is thicker than the first thickness T1.
(13)

The imaging device according to (12), in which in a case where the second width W2 is ½ of the first width W1, the second thickness T2 is twice the first thickness T1.
(14)

The imaging device according to any one of (1) to (13), in which a plurality of the on-chip lenses is provided for each of the pixels.
(15)

The imaging device according to any one of (1) to (13), in which one of the on-chip lenses is provided for a plurality of the pixels.
(16)

The imaging device according to any one of (1) to (15), further including:
a color filter provided between the pixel region and the on-chip lens; and
a first light shielding film provided in the color filter on between the pixels adjacent to each other.
(17)

The imaging device according to (16), further including a second light shielding film on the first light shielding film on between the adjacent pixels.
(18)

An imaging device including:
a pixel region in which a plurality of pixels that performs photoelectric conversion is arranged;
an on-chip lens provided on the pixel region;
a protective member provided on the on-chip lens;
a resin layer that adheres between the on-chip lens and the protective member; and
a lens provided on the protective member.
(19)

An imaging device including:
a pixel region in which a plurality of pixels that performs photoelectric conversion is arranged;
a plurality of on-chip lenses provided on the pixel region and provided for each of the pixels;
a protective member provided on the on-chip lenses; and
a resin layer that adheres between the on-chip lenses and the protective member.
(20)

An imaging device including:
a pixel region in which a plurality of pixels that performs photoelectric conversion is arranged;
an on-chip lens provided on the pixel region and provided for each of a plurality of the pixels;
a protective member provided on the on-chip lens; and
a resin layer that adheres between the on-chip lens and the protective member.
(21)

An imaging device including:
a pixel region in which a plurality of pixels that performs photoelectric conversion is arranged;
an on-chip lens provided on the pixel region and provided for each of a plurality of the pixels;
a color filter provided between the pixel region and the on-chip lens;
a first light shielding film provided in the color filter on between the pixels adjacent to each other;
a protective member provided on the color filter and the first light shielding film; and
a resin layer that adheres between the on-chip lens and the protective member.
(22)

The imaging device according to any one of (1) to (21), in which the pixel region includes at least an effective pixel region that outputs a pixel signal used to generate an image.
(23)

The imaging device according to (22), in which the pixel region further includes an optical black (OB) pixel region that outputs a pixel signal serving as a reference of dark output.
(24)

The imaging device according to (23), in which the OB pixel region is provided so as to surround a periphery of the effective pixel region.
(25)

The imaging device according to (23), in which the pixel region further includes a dummy pixel region that stabilizes characteristics of the effective pixel region.
(26)

The imaging device according to (25), in which the dummy pixel region is provided so as to surround a periphery of the OB pixel region.
(27)

The imaging device according to any one of (1) to (21), in which the pixel region includes an effective photosensitive region in which the pixels including photodiodes are arranged.
(28)

The imaging device according to (27), in which the pixel region further includes an external region in which the pixels including the photodiodes are not arranged.
(29)

The imaging device according to (28), in which the external region is provided around the effective photosensitive region.
(30)

The imaging device according to (29), in which the pixel region further includes a termination region that cuts a semiconductor package from a wafer.
(31)

The imaging device according to (30), in which the termination region is provided around the external region.

Note that the present disclosure is not limited to the above-described embodiments, and various modifications can be made without departing from the gist of the present disclosure. Furthermore, the effects described in this specification are merely examples and are not limited, and other effects may be present.

### REFERENCE SIGNS LIST

1 Solid-state imaging device
11 Lower substrate
12 Upper substrate
15 Color filter
16 On-chip lens
17 Sealing resin
18 Protective member
21 Pixel region
22 Control circuit
23 Logic circuit
32 Pixel

What is claimed is:

1. An imaging device, comprising:
a pixel region in which a plurality of pixels that performs photoelectric conversion is arranged;
an on-chip lens provided on the pixel region;
a protective member provided on the on-chip lens; and
a resin layer that adheres between the on-chip lens and the protective member,
wherein when a thickness of the resin layer and the protective member is T, a length of a diagonal line of the pixel region viewed from an incident direction of light is L, and a critical angle of the protective member is θc,
T≥L/2/tan θc (Formula 2)
T≥L/4/tan θc (Formula 3)
Formula 2 or 3 is satisfied.

2. The imaging device according to claim 1, wherein
glass is used for the protective member, and
the critical angle θc is about 41.5°.

3. The imaging device according to claim 1, further comprising a concave lens provided on the protective member.

4. The imaging device according to claim 1, further comprising a convex lens provided on the protective member.

5. The imaging device according to claim 1, further comprising an actuator that is provided under the protective member or in the protective member and changes a thickness of the protective member.

6. The imaging device according to claim 1, further comprising a light absorbing film provided on a side surface of the protective member.

7. The imaging device according to claim 1, further comprising an antireflection film provided on the protective member.

8. The imaging device according to claim 1, further comprising an infrared cut filter provided on the protective member or in the protective member.

9. The imaging device according to claim 1, further comprising a Fresnel lens provided on the protective member.

10. The imaging device according to claim 1, further comprising a metalens provided on the protective member.

11. The imaging device according to claim 1, further comprising a light shielding film provided on the protective member and including a hole.

12. The imaging device according to claim 1, wherein
the thickness T is greater than or equal to a first thickness T1 when a width of the pixel is a first width W1 in a plan view viewed from the incident direction, and
when the width of the pixel is a second width W2 (W2<W1) smaller than the first width, the thickness T is greater than or equal to a second thickness T2 (T2>T1) that is thicker than the first thickness T1.

13. The imaging device according to claim 12, wherein in a case where the second width W2 is ½ of the first width W1, the second thickness T2 is twice the first thickness T1.

14. The imaging device according to claim 1, wherein a plurality of the on-chip lenses is provided for each of the pixels.

15. The imaging device according to claim 1, wherein one of the on-chip lenses is provided for a plurality of the pixels.

16. The imaging device according to claim 1, further comprising:
a color filter provided between the pixel region and the on-chip lens; and
a first light shielding film provided in the color filter on between the pixels adjacent to each other.

17. The imaging device according to claim 16, further comprising a second light shielding film on the first light shielding film on between the adjacent pixels.

18. An imaging device, comprising:
a pixel region in which a plurality of pixels that performs photoelectric conversion is arranged;
an on-chip lens provided on the pixel region;
a protective member provided on the on-chip lens;
a resin layer that adheres between the on-chip lens and the protective member; and
a lens provided on the protective member.

19. An imaging device, comprising:
a pixel region in which a plurality of pixels that performs photoelectric conversion is arranged;
a plurality of on-chip lenses provided on the pixel region and provided for each of the pixels;
a protective member provided on the on-chip lenses; and
a resin layer that adheres between the on-chip lenses and the protective member.

20. An imaging device, comprising:
a pixel region in which a plurality of pixels that performs photoelectric conversion is arranged;
an on-chip lens provided on the pixel region and provided for each of a plurality of the pixels;
a protective member provided on the on-chip lens; and
a resin layer that adheres between the on-chip lens and the protective member.

21. An imaging device, comprising:
a pixel region in which a plurality of pixels that performs photoelectric conversion is arranged;
an on-chip lens provided on the pixel region and provided for each of a plurality of the pixels;
a color filter provided between the pixel region and the on-chip lens;
a first light shielding film provided in the color filter on between the pixels adjacent to each other;
a protective member provided on the color filter and the first light shielding film; and
a resin layer that adheres between the on-chip lens and the protective member.

22. The imaging device according to claim 1, wherein the pixel region includes at least an effective pixel region that outputs a pixel signal used to generate an image.

23. The imaging device according to claim 22, wherein the pixel region further includes an optical black (OB) pixel region that outputs a pixel signal serving as a reference of dark output.

24. The imaging device according to claim 23, wherein the OB pixel region is provided so as to surround a periphery of the effective pixel region.

25. The imaging device according to claim 23, wherein the pixel region further includes a dummy pixel region that stabilizes a characteristic of the effective pixel region.

26. The imaging device according to claim 25, wherein the dummy pixel region is provided so as to surround a periphery of the OB pixel region.

27. The imaging device according to claim 1, wherein the pixel region includes an effective photosensitive region in which the pixels including photodiodes are arranged.

28. The imaging device according to claim 27, wherein the pixel region further includes an external region in which the pixels including the photodiodes are not arranged.

29. The imaging device according to claim 28, wherein the external region is provided around the effective photosensitive region.

30. The imaging device according to claim 29, wherein the pixel region further includes a termination region that cuts a semiconductor package from a wafer.

31. The imaging device according to claim 30, wherein the termination region is provided around the external region.
